(19) United States
(12) Patent Application Publication
(10) Pub. No.: US 2025/0112617 A1
(43) Pub. Date: Apr. 3, 2025

(54) RESONATOR WITH OPTIMIZED LAYER THICKNESSES

(71) Applicant: Murata Manufacturing Co., Ltd., Nagaokakyo-shi (JP)

(72) Inventors: Drew MOROSIN, Oxnard, CA (US); John P. KOULAKIS, Los Angeles, CA (US); Garrett WILLIAMS, San Mateo, CA (US)

(21) Appl. No.: 18/897,043

(22) Filed: Sep. 26, 2024

Related U.S. Application Data
(60) Provisional application No. 63/586,815, filed on Sep. 29, 2023.

(51) Int. Cl. H03H 9/13; H03H 3/02; H03H 9/02; H03H 9/17

(52) U.S. Cl. CPC H03H 9/132; H03H 3/02; H03H 9/02157; H03H 9/02228; H03H 9/173; H03H 9/174; H03H 9/175; H03H 9/176

(57) ABSTRACT

An acoustic resonator is provided that includes an interdigital transducer (IDT) at a surface of at least one piezoelectric layer, the IDT including interleaved IDT fingers extending from first and second busbars respectively. Moreover, a ratio of a thickness of the IDT fingers to a thickness of the at least one piezoelectric layer is optimized to minimize unwanted spurs. The mark to pitch ratio of the IDT fingers may also be optimized to minimize spurs during operation.

### CROSS REFERENCE TO RELATED APPLICATIONS

This application claims priority to U.S. Patent Provisional Application No. 63/586,815, filed Sep. 29, 2023, the entire contents of which are hereby incorporated by reference.

### TECHNICAL FIELD

This disclosure relates to radio frequency filters using acoustic wave resonators, and, more specifically, to a filter including an acoustic wave resonator having optimized layer thicknesses for operation in a higher-order mode.

### BACKGROUND

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “passband” of the filter. The range of frequencies stopped by such a filter is referred to as the “stopband” of the filter. A typical RF filter has at least one passband and at least one stop-band. Specific requirements on a passband or stop-band may depend on the specific application. For example, in some cases a “passband” may be defined as a frequency range where the insertion loss of a filter is better than a defined value such as 1 dB, 2 dB, or 3 dB, while a “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

Performance enhancements to the RF filters in a wireless system can have a broad impact on system performance, especially for the acoustic resonators of an RF filter operating at higher modes. Improvements in RF filters can be leveraged to provide system performance improvements, such as larger cell size, longer battery life, higher data rates, greater network capacity, lower cost, enhanced security, higher reliability, etc. These improvements can be realized at many levels of the wireless system both separately and in combination, for example, at the RF module, RF transceiver, mobile or fixed sub-system, or network levels.

The transversely-excited film bulk acoustic resonator (XBAR) is an acoustic resonator structure for use in microwave filters. An XBAR resonator typically comprises an interdigital transducer (IDT) formed on a thin floating layer, or diaphragm, of a single-crystal piezoelectric material. The IDT includes a first set of parallel fingers, extending from a first busbar and a second set of parallel fingers extending from a second busbar. The first and second sets of parallel fingers are interleaved. A microwave signal applied to the IDT excites a shear primary acoustic wave in the piezoelectric diaphragm. XBAR resonators provide very high electromechanical coupling and high frequency capability. XBAR resonators may be used in a variety of RF filters including band-reject filters, bandpass filters, duplexers, and multiplexers. XBARs are well suited for use in filters for communications bands with frequencies above 3 GHz.

### SUMMARY

Accordingly, as described herein, an acoustic resonator and filter device incorporating the same is provided having optimized layer thicknesses for operation in an asymmetric third-order (A3) mode, or another higher-order mode, to meet high frequency and narrow bandwidth requirements.

Thus, according to an exemplary aspect, a bulk acoustic resonator device is provided that is configured for operating in a third-order antisymmetric (A3) mode. In this aspect, the bulk acoustic resonator device includes a substrate; a piezoelectric layer connected directly or via one or more intermediate layers to the substrate; and an interdigital transducer (IDT) on a surface of the piezoelectric layer, the IDT including interleaved IDT fingers extending from first and second busbars respectively. Moreover, a ratio of a thickness of the IDT fingers to a thickness of the piezoelectric layer is between 0.38 and 0.66, the thickness of the IDT fingers and the thickness of the piezoelectric layer being measured in a direction normal to the surface of the piezoelectric layer.

In another exemplary aspect of the bulk acoustic resonator device, the piezoelectric layer is one of (i) at least one lithium niobate plate or (ii) at least one lithium tantalate plate, and the IDT fingers are aluminum.

In another exemplary aspect of the bulk acoustic resonator device, a ratio of a mark of the IDT fingers to a pitch of the IDT fingers is in a range of 0.1 to 0.4, and the mark of the IDT fingers and the pitch of the IDT fingers being measured in a direction that is substantially parallel to the surface of the piezoelectric layer.

In another exemplary aspect of the bulk acoustic resonator device, a ratio of a pitch of the IDT fingers to the thickness of the piezoelectric layer is 5.5.

In another exemplary aspect, the bulk acoustic resonator device further comprises a diaphragm comprising a portion of the piezoelectric layer over a cavity of the bulk acoustic resonator device.

In another exemplary aspect, the bulk acoustic resonator device further comprises at least one of a front side dielectric layer at a front surface of the piezoelectric layer; or a back side dielectric layer at a back surface of the piezoelectric layer.

In another exemplary aspect of the bulk acoustic resonator device, the piezoelectric layer and the IDT are configured such that a radio frequency signal applied to the IDT excites a primarily shear acoustic mode within the piezoelectric layer. Moreover, the radio frequency signal applied to the IDT excites an IDT acoustic mode among structures of the IDT, a frequency of the IDT acoustic mode being matched to a primarily shear acoustic wave within the piezoelectric layer.

In another exemplary aspect of the bulk acoustic resonator device, the radio frequency signal is within a range defined by 13.2 GHz and 13.5 GHz, inclusive.

In another exemplary aspect of the bulk acoustic resonator device, the bulk acoustic resonator device is configured to excite a bulk shear wave having a propagation direction perpendicular to a direction of a primarily laterally excited electric field generated by the IDT, the electric field being primarily laterally excited when atomic motion of the bulk shear wave is primarily horizontal in the piezoelectric layer, while the bulk shear wave propagates in a direction primarily perpendicular to the direction of atomic motion.

In another exemplary aspect, a bulk acoustic resonator device is provided that includes, a substrate; a piezoelectric layer attached directly or via one or more intermediate layers to the substrate; and an interdigital transducer (IDT) on a surface of the piezoelectric layer, the IDT including interleaved IDT fingers extending from first and second busbars respectively. In this aspect, a ratio of a thickness of the IDT fingers to a thickness of the piezoelectric layer is between 0.38 and 0.66, the thickness of the IDT fingers and the thickness of the piezoelectric layer being measured in a direction normal to the surface of the piezoelectric layer. Moreover, a ratio of a mark of the IDT fingers to a pitch of the IDT fingers is in a range of 0.1 to 0.4, the mark of the IDT fingers and the pitch of the IDT fingers being measured in a direction that is substantially parallel to the surface of the piezoelectric layer.

In another exemplary aspect, a radio frequency module is provided that includes a filter device having a plurality of acoustic resonators configured to operate in a third-order antisymmetric (A3) mode; and a radio frequency circuit coupled to the filter device, the filter device and the radio frequency circuit being enclosed within a common package. In this aspect, at least one of the plurality of acoustic resonators includes a substrate; a piezoelectric layer connected directly or via one or more intermediate layers to the substrate; and an interdigital transducer (IDT) on a surface of the piezoelectric layer, the IDT including interleaved IDT fingers extending from first and second busbars respectively. Moreover, a ratio of a thickness of the IDT fingers to a thickness of the piezoelectric layer is between 0.38 and 0.66, the thickness of the IDT fingers and the thickness of the piezoelectric layer being measured in a direction normal to the surface of the piezoelectric layer.

The above simplified summary of example aspects serves to provide a basic understanding of the present disclosure. This summary is not an extensive overview of all contemplated aspects and is intended to neither identify key or critical elements of all aspects nor delineate the scope of any or all aspects of the present disclosure. Its sole purpose is to present one or more aspects in a simplified form as a prelude to the more detailed description of the disclosure that follows. To the accomplishment of the foregoing, the one or more aspects of the present disclosure include the features described and exemplary pointed out in the claims.

### BRIEF DESCRIPTION OF THE DRAWINGS

The accompanying drawings, which are incorporated into and form a part of this specification, illustrate one or more example aspects of the present disclosure and, together with the detailed description, serve to explain their principles and implementations.

FIG. 1A includes a schematic plan view and a schematic cross-sectional view of a transversely-excited film bulk acoustic resonator (XBAR).

FIG. 1B shows a schematic cross-sectional view of an alternative configuration of an XBAR.

FIG. 2A is an expanded schematic cross-sectional view of a portion of the XBAR of FIG. 1A.

FIG. 2B is an expanded schematic cross-sectional view of an alternative configuration of the XBAR of FIG. 1A.

FIG. 2C is an expanded schematic cross-sectional view of another alternative configuration of the XBAR of FIG. 1A.

FIG. 2D is an expanded schematic cross-sectional view of another alternative configuration of the XBAR of FIG. 1A.

FIG. 2E is an expanded schematic cross-sectional view of a portion of a solidly-mounted XBAR (SM XBAR).

FIG. 3A is a schematic cross-sectional view of an XBAR according to an exemplary aspect.

FIG. 3B is an alternative schematic cross-sectional view of an XBAR according to an exemplary aspect.

FIG. 4A is a graphical illustration of a shear horizontal acoustic mode in an exemplary aspect of the XBAR.

FIG. 4B is a graphic illustrating a shear horizontal acoustic mode in an XBAR operating in a third-order antisymmetric (A3) mode.

FIG. 5A is a schematic block diagram of a filter using XBARs of FIGS. 1A and/or 1B.

FIG. 5B is a schematic diagram of a radio frequency module that includes an acoustic wave filter device according to an exemplary aspect.

FIGS. 6A to 6C are graphs showing mode spectrum of propagating modes within the IDT region (i.e., the piezoelectric layer with the metal IDT layer) and the propagating modes corresponding frequency multiplied by the metal thickness against an increasing metal thickness.

FIG. 7 is a graph identifying preferred combinations of IDT finger thickness, mark of the IDT fingers, and a ratio of the thickness of the IDT fingers to the thickness of the piezoelectric layer.

FIG. 8 is a flow chart of a method for fabricating an XBAR or a filter using XBARs according to an exemplary aspect.

Throughout this description, elements appearing in figures are assigned three-digit or four-digit reference designators, where the two least significant digits are specific to the element and the one or two most significant digits are the figure number where the element is first introduced. An element that is not described in conjunction with a figure may be presumed to have the same characteristics and function as a previously described element having the same reference designator.

### DETAILED DESCRIPTION

Various aspects of the disclosed acoustic resonator, filter device and method of manufacturing the same are now described with reference to the drawings, wherein like reference numerals are used to refer to like elements throughout. In the following description, for purposes of explanation, numerous specific details are set forth in order to promote a thorough understanding of one or more aspects of the disclosure. It may be evident in some or all instances, however, that any aspects described below can be practiced without adopting the specific design details described below. In other instances, well-known structures and devices are shown in block diagram form in order to facilitate description of one or more aspects. The following presents a simplified summary of one or more aspects of the invention in order to provide a basic understanding thereof.

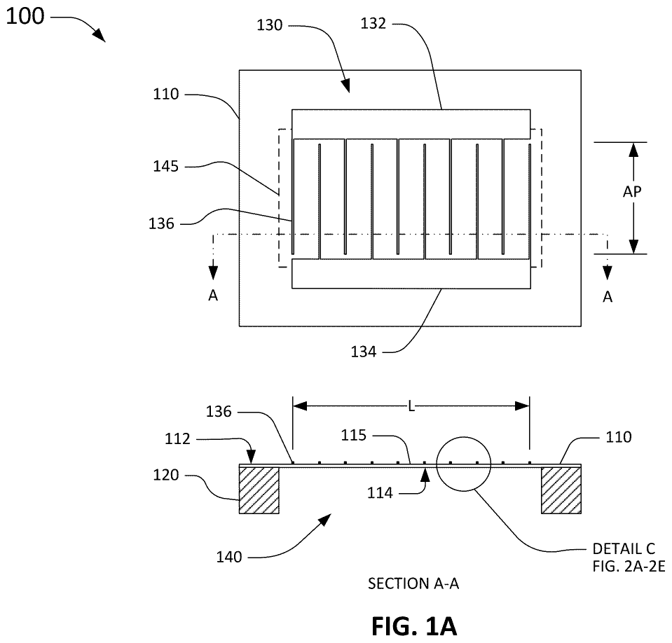

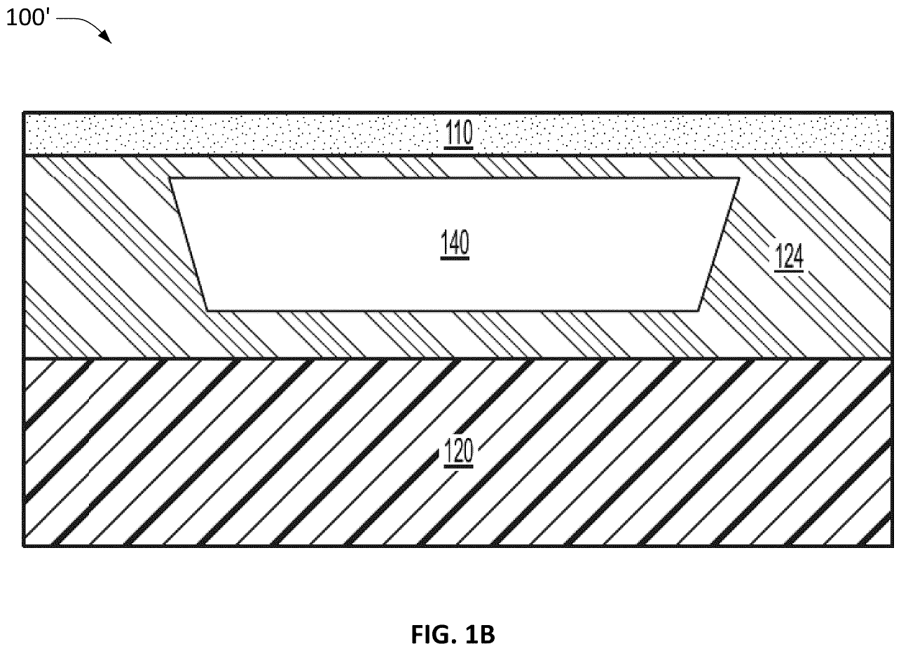

FIG. 1A shows a simplified schematic top view and an orthogonal cross-sectional view of a bulk acoustic resonator device, namely a transversely excited film bulk acoustic resonator (XBAR) 100. XBAR resonators, such as the resonator 100, may be used in a variety of RF filters including band-rejection filters, bandpass filters, duplexers, and multiplexers. XBARs are particularly suited for use in filters for communications bands with frequencies above 3 GHz.

In general, the XBAR 100 includes a conductor pattern (e.g., a thin film metal layer) formed at one or both surfaces of a piezoelectric layer 110 (herein piezoelectric plate or piezoelectric layer may be used interchangeably) having parallel front side 112 and a back side 114, respectively (also referred to generally first and second surfaces, respectively). It should be appreciated that the term “parallel” generally refers to the front side 112 and back side 114 being opposing to each other and that the surfaces are not necessarily planar and exactly parallel to each other. For example, due to the manufacturing variances result from the deposition process, the front side 112 and back side 114 may have undulations of the surface as would be appreciated to one skilled in the art. Moreover, the term “substantially” (e.g., “substantially parallel”) as used herein is used to describe when components, parameters and the like are generally the same (i.e., “substantially constant”), but may vary slightly (e.g., within an acceptable threshold or percentage) in practice due to possible manufacturing variances as would be appreciated to one skilled in the art. For purposes of this disclosure, the use of the term “or” in the claims is used to mean “and/or” unless explicitly indicated to refer to alternatives only or if the alternatives are mutually exclusive.

According to an exemplary aspect, the piezoelectric layer can be a thin single-crystal layer of a piezoelectric material, such as lithium niobate, lithium tantalate, lanthanum gallium silicate, gallium nitride, or aluminum nitride. It should be appreciated that the term “single-crystal” does not necessarily mean entirely of a uniform crystalline structure and may include impurities due to manufacturing variances as long as the crystal structure is within acceptable tolerances. The piezoelectric layer is cut such that the orientation of the X, Y, and Z crystalline axes with respect to the front and back sides is known and consistent. In the examples described herein, the piezoelectric layers are Z-cut, which is to say the Z axis is normal to the front and back sides 112, 114. However, XBARs may be fabricated on piezoelectric layers with other crystallographic orientations including rotated Z-cut, Y-cut and rotated YX cut.

The Y-cut family, such as 120Y and 128Y, are typically referred to as 120YX or 128YX, where the “cut angle” is the angle between the y axis and the normal to the layer. The “cut angle” is equal to β+90°. For example, a layer with Euler angles [0°, 30°, 0°] is commonly referred to as “120° rotated Y-cut” or “120Y.” Thus, the Euler angles for 120YX and 128YX are (0, 120-90,0) and (0, 128-90,0) respectively. A “Z-cut” is typically referred to as a ZY cut and is understood to mean that the layer surface is normal to the Z axis but the wave travels along the Y axis. The Euler angles for ZY cut are (0, 0, 90).

The back side 114 of the piezoelectric layer 110 may be at least partially supported by a surface of the substrate 120 except for a portion of the piezoelectric layer 110 that forms a diaphragm 115 that is over (e.g., spanning or extending over) a cavity 140 in one or more layers below the piezoelectric layer 110 such as one or more intermediate layers above or in the substrate. In other words, the back side 114 of the piezoelectric layer 110 can be coupled or connected either directly or indirectly, via one or more intermediate layers (e.g., a dielectric layer, such as a silicon oxide layer), to a surface of the substrate 120. Moreover, the phrase “supported by” or “attached” may, as used herein interchangeably, mean attached directly, attached indirectly, mechanically supported, structurally supported, or any combination thereof. The portion of the piezoelectric layer that is over (e.g., spanning or extending over) the cavity can be referred to herein as a “diaphragm” 115 due to its physical resemblance to the diaphragm of a microphone. As shown in FIG. 1A, the diaphragm 115 is contiguous with the rest of the piezoelectric layer 110 around all of a perimeter 145 of the cavity 140. In this context, “contiguous” means “continuously connected without any intervening item”. However, the diaphragm 115 can be configured with at least 50% of the edge surface of the diaphragm 115 coupled to the edge of the piezoelectric layer 110 in an exemplary aspect.

According to the exemplary aspect, the substrate 120 is configured to provide mechanical support to the piezoelectric layer 110. The substrate 120 may be, for example, silicon, sapphire, quartz, or some other material or combination of materials. The back side 114 of the piezoelectric layer 110 may be bonded to the substrate 120 using a wafer bonding process. Alternatively, the piezoelectric layer 110 may be grown on the substrate 120 or supported by, or attached to, the substrate in some other manner.

For purposes of this disclosure, “cavity” has its conventional meaning of “an empty space within a solid body.” The cavity 140 may be a hole completely through the substrate 120 (as shown in Section A-A), a hole within a dielectric layer (as shown in FIG. 1B), or a recess in the substrate 120. The cavity 140 may be formed, for example, by selective etching of the substrate 120 before or after the piezoelectric layer 110 and the substrate 120 are attached, either directly or indirectly.

As shown, the conductor pattern of the XBAR 100 includes an interdigital transducer (IDT) 130. The IDT 130 includes a first plurality of parallel fingers, such as finger 136, extending from a first busbar 132 and a second plurality of fingers extending from a second busbar 134. The first and second pluralities of parallel fingers are interleaved with each other that can be “substantially” parallel to each other due to minor variations, such as due to manufacturing tolerances, for example. At least a portion of the interleaved fingers overlap for a distance AP, commonly referred to as the “aperture” of the IDT. The center-to-center distance L between the outermost fingers of the IDT 130 is the “length” of the IDT.

In the example of FIG. 1A, the IDT 130 is at the surface of the front side 112 (e.g., the first surface) of the piezoelectric layer 110. However, as discussed below, in other configurations, the IDT 130 may be at the surface of the back side 114 (e.g., the second surface) of the piezoelectric layer 110 or at both the surfaces of the front and back sides 112, 114 of the piezoelectric layer 110, respectively.

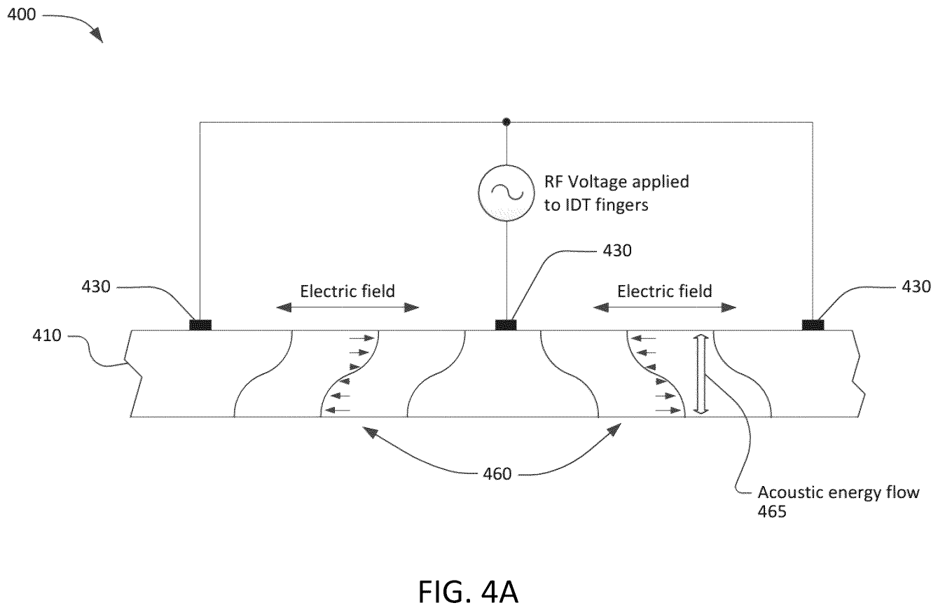

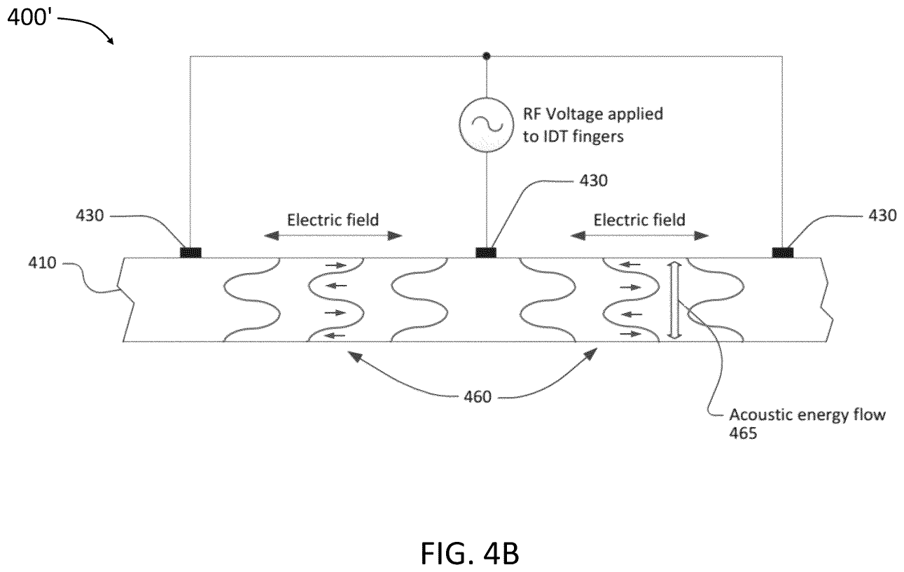

The first and second busbars 132, 134 are configured as the terminals of the XBAR 100 with the plurality of interleaved fingers extending therefrom. In operation, a radio frequency signal or microwave signal applied between the two busbars 132, 134 of the IDT 130 primarily excites an acoustic mode (i.e., a primarily shear acoustic mode) within the piezoelectric layer 110. As will be discussed in further detail, the primarily excited shear acoustic mode is a bulk shear mode or bulk acoustic wave where acoustic energy of a bulk shear acoustic wave is excited in the piezoelectric layer 110 by the IDT 130 and propagates along a direction substantially, predominantly, and/or primarily orthogonal to the surface of the piezoelectric layer 110, which is also primarily normal, or transverse, to the direction of the electric field created by the IDT fingers. That is, when a radio frequency or a microwave signal is applied between the two busbars 132, 134, the RF voltage applied to the respective sets of IDT fingers generates a time-varying electric field that is laterally excited with respect to a surface of the piezoelectric layer 110. Thus, in some cases the primarily excited acoustic mode may be commonly referred to as a laterally excited bulk acoustic wave since displacement, as opposed to propagation, occurs primarily in the direction of the bulk of the piezoelectric layer, as discussed in more detail below in reference to FIGS. 4A and 4B.

For purposes of this disclosure, “primarily acoustic mode” may generally refer to an operational mode in which a vibration displacement is caused in the primarily thickness-shear direction (e.g., X-direction), so the wave propagates substantially and/or primarily in the direction connecting front and back surfaces of the piezoelectric layer, that is, in the Z direction. In other words, the X-direction component of the wave is significantly smaller than the Z-direction component. The use of the term “primarily” in the “primarily excited acoustic mode” is not necessarily referring to a lower or higher order mode. Thus, the XBAR is considered a transversely excited film bulk wave resonator. One physical constraint is that when the radio frequency or microwave signal is applied between the two busbars 132, 134 of the IDT 130, heat is generated that must be dissipated from the resonator for improved performance. In general, heat can be dissipated by lateral conduction on the membrane (e.g., in the electrodes themselves), and vertical conduction through a cavity to substrate.

In any event, the IDT 130 is positioned at or on the piezoelectric layer 110 such that at least the fingers of the IDT extend at or on the portion of the piezoelectric layer 110 that is over the cavity 140, for example, the diaphragm 115 as described herein. As shown in FIG. 1A, the cavity 140 has a rectangular cross section with an extent greater than the aperture AP and length L of the IDT 130. According to other exemplary aspects, the cavity of an XBAR may have a different cross-sectional shape, such as a regular or irregular polygon. The cavity of an XBAR may have more or fewer than four sides, which may be straight or curved.

According to an exemplary aspect, the area of XBAR 100 is determined as the area of the IDT 130. For example, the area of the IDT 130 can be determined based on the measurement of the length L multiplied by the width of the aperture AP of the interleaved fingers of the IDT 130. As used herein through the disclosure, area is referenced in μm². Thus, the area of the XBAR 100 may be adjusted based on design choices, as described below, thereby adjusting the overall capacitance of the XBAR 100.

For ease of presentation in FIG. 1A, the geometric pitch and width of the IDT fingers is greatly exaggerated with respect to the length (dimension L) and aperture (dimension AP) of the XBAR. A typical XBAR has more than ten parallel fingers in the IDT. For example, an XBAR may have hundreds, possibly thousands, of parallel fingers in the IDT according to exemplary aspects. Similarly, the thickness of the fingers in the cross-sectional views is greatly exaggerated.

FIG. 1B shows a schematic cross-sectional view of an alternative XBAR configuration 100′. In FIG. 1B, the cavity 140 (which can correspond generally to cavity 140 of FIG. 1A) of the resonator 100′ is formed entirely within a dielectric layer 124 (for example silicon oxide or silicon dioxide, as in FIG. 1B) that is located between the substrate 120 (indicated as Si in FIG. 1B) and the piezoelectric layer 110 (indicated as LN in FIG. 1B). Although a single dielectric layer 124 is shown having cavity 140 formed therein (e.g., by etching), it should be appreciated that the dielectric layer 124 can be formed by a plurality of separate dielectric layers formed on each other to provide a stack of materials.

Moreover, in the example of FIG. 1B, the cavity 140 is defined on all sides by the dielectric layer 124. However, in other exemplary embodiments, one or more sides of the cavity 140 may be defined by the substrate 120 and/or the piezoelectric layer 110. In the example of FIG. 1B, the cavity 140 has a trapezoidal shape. However, as noted above, cavity shape is not limited and may be rectangular, oval, or other shapes.

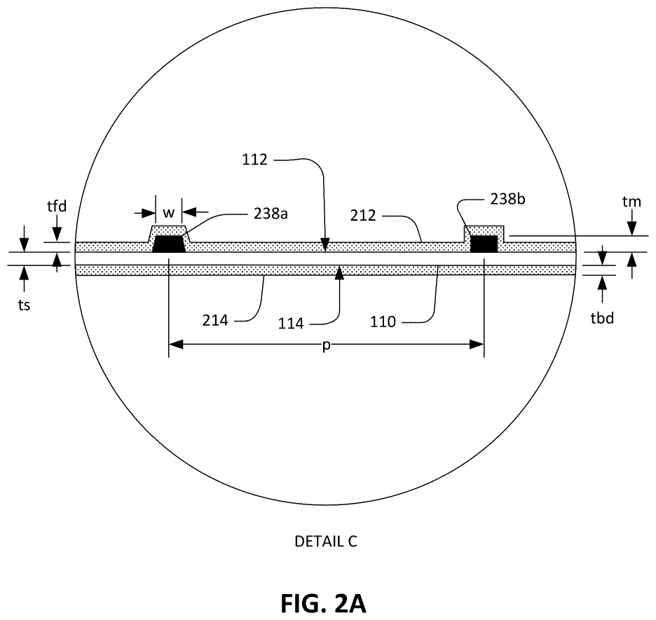

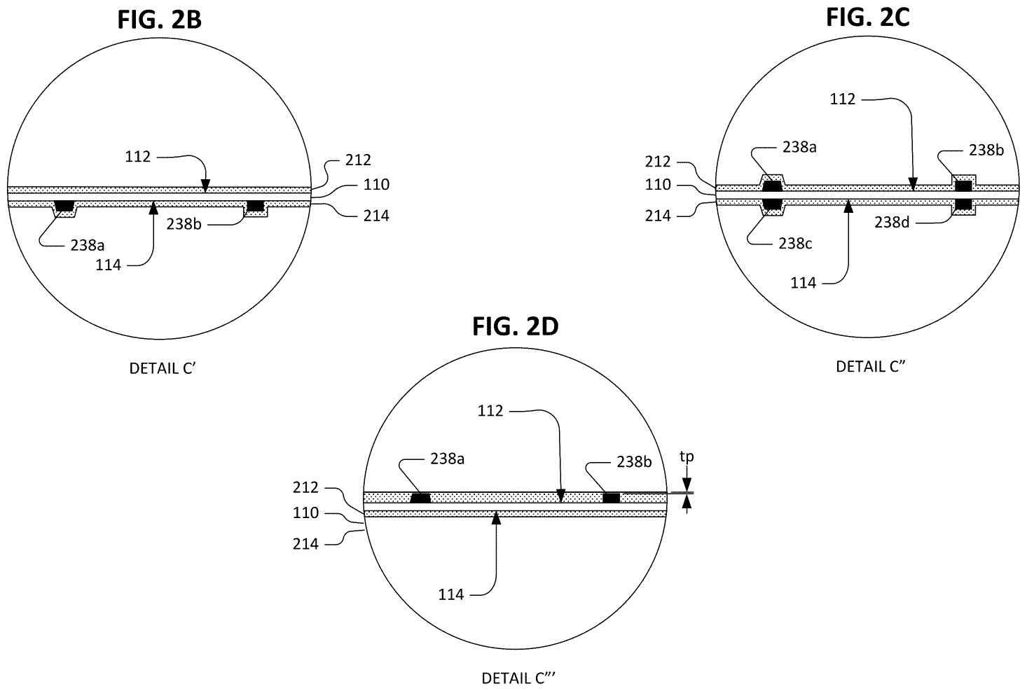

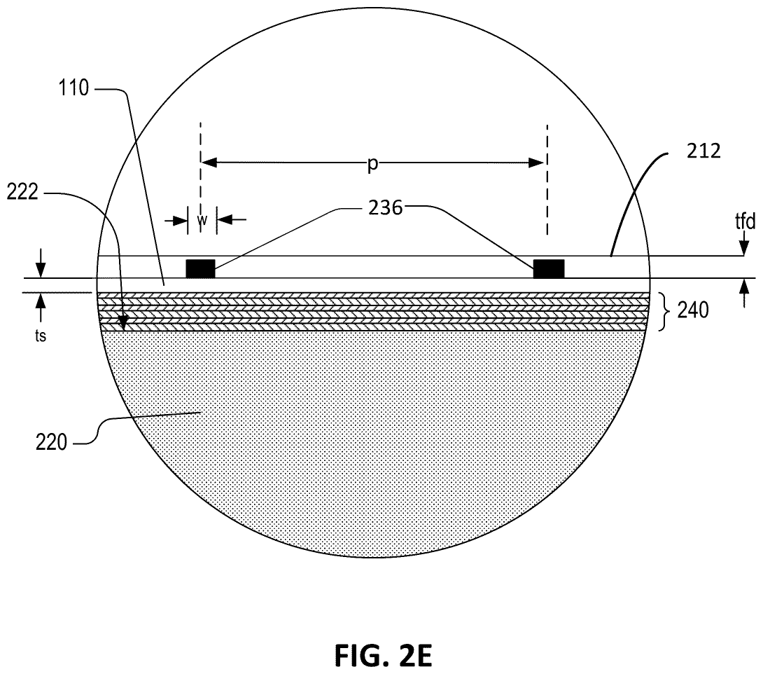

FIG. 2A shows a detailed schematic cross-sectional view (labeled as Detail C) of the XBAR 100 of FIG. 1A or 1B. The piezoelectric layer 110 is a single-crystal layer of piezoelectrical material having a thickness ts. Ts may be, for example, 100 nanometers (nm) to 1500 nm. When used in filters for 5G NR and Wi-Fi™ bands from 3.4 GHz to 7 GHz, the thickness ts may be, for example, 150 nm to 500 nm. The thickness ts can be measured in a direction substantially perpendicular or orthogonal to a surface of the piezoelectric layer in an exemplary aspect.

In this aspect, a front side dielectric layer 212 (e.g., a first dielectric coating layer or material) can be formed on the front side 112 of the piezoelectric layer 110. The “front side” of the XBAR is, by definition, the surface facing away from the substrate. The front side dielectric layer 212 has a thickness tfd. As shown in FIG. 2A the front side dielectric layer 212 covers the IDT fingers 238a, 238b, which can correspond to fingers 136 as described above with respect to FIG. 1A. Although not shown in FIG. 2A, the front side dielectric layer 212 may also be deposited only between the IDT fingers 238a, 238b. In this case, an additional thin dielectric layer (not shown) may be deposited over the IDT fingers to seal and passivate the fingers. Further, although also not shown in FIG. 2A, the front side dielectric layer 212 may also be deposited only on select IDT fingers 238a, for example.

A back side dielectric layer 214 (e.g., a second dielectric coating layer or material) can also be formed on the back side of the back side 114 of the piezoelectric layer 110. In general, for purposes of this disclosure, the term “back side” means on a side opposite the conductor pattern of the IDT structure and/or opposite the front side dielectric layer 212. Moreover, the back side dielectric layer 214 has a thickness tbd. The front side and back side dielectric layers 212, 214 may be a non-piezoelectric dielectric material, such as silicon oxide, silicon dioxide or silicon nitride. Tfd and tbd may be, for example, 0 to 500 nm. Tfd and tbd may be less than the thickness ts of the piezoelectric layer. Tfd and tbd are not necessarily equal, and the front side and back side dielectric layers 212, 214 are not necessarily the same material. In exemplary aspects, either or both of the front side and back side dielectric layers 212, 214 may be formed of multiple layers of two or more materials according to various exemplary aspects.

The IDT fingers 238a, 238b may comprise aluminum, substantially (i.e., predominantly) aluminum alloys, copper, substantially (i.e., predominantly) copper alloys, beryllium, gold, or some other conductive material. Thin (relative to the total thickness of the conductors) layers of other metals, such as chromium or titanium, may be formed under and/or over the fingers to improve adhesion between the fingers and the piezoelectric layer 110 and/or to passivate or encapsulate the fingers. The busbars (132, 134 in FIG. 1A) of the IDT may be made of the same or different materials as the fingers. The cross-sectional shape of the IDT fingers may be trapezoidal (finger 238a), rectangular (finger 238b) or some other shape in various exemplary aspects. In general, it is noted that the terms “comprise”, “have”, “include” and “contain” (and their variants) as used herein are open-ended linking verbs and allow the addition of other elements when used in a claim. Moreover, the use of the word “a” or “an” when used in conjunction with the term “comprising” in the claims or the specification means one or more than one, unless the context dictates otherwise.

Dimension p (i.e., the “pitch”) can be considered the center-to-center spacing between adjacent IDT fingers, such as the IDT fingers 238a, 238b in FIGS. 2A-2D. Center points of center-to-center spacing may be measured at a center of the width “w” of a finger as shown in FIG. 2A. In some cases, the center-to-center spacing may change if the width of a given finger changes along the length of the finger, if the width and extending direction changes, or any variation thereof. In that case, for a given location along AP, center-to-center spacing may be measured as an average center-to-center spacing, a maximum center-to-center spacing, a minimum center-to-center spacing, or any variation thereof. Adjacent fingers may each extend from a different busbar and center-to-center spacing may be measured from a center of a first finger extending from a first busbar to a center of a second finger, adjacent to the first finger, extending from a second busbar. The center-to-center spacing may be constant over the length of the IDT, in which case the dimension p may be referred to as the pitch of the IDT and/or the pitch of the XBAR. However, in an alternative exemplary aspect, the center-to-center spacing varies along the length of the IDT, in which case the pitch of the IDT may be the average value of dimension p over the length of the IDT. Center-to-center spacing from one finger to an adjacent finger may vary continuously when compared to other adjacent fingers, in discrete sections of multiple adjacent pairs, or any combination thereof. Each IDT finger, such as the IDT fingers 238a, 238b in FIGS. 2A to 2D, has a width w measured normal to the long direction of each finger. The width w may also be referred to herein as the “mark.” In general, the width of the IDT fingers may be constant over the length of the IDT, in which case the dimension w may be the width of each IDT finger. However, in another exemplary aspect as will be discussed below, the width of individual IDT fingers varies along the length of the IDT 130, in which case dimension w may be the average value of the widths of the IDT fingers over the length of the IDT. Note that the pitch p and the width w of the IDT fingers are measured in a direction substantially parallel to the length L of the IDT, as defined in FIG. 1A.

In general, the IDT of an XBAR differs substantially from the IDTs used in surface acoustic wave (SAW) resonators, primarily in that IDTs of an XBAR excite a primary shear acoustic mode (also referred to as a primary shear mode, a primary shear thickness mode, or the like), as described in more detail below with respect to FIGS. 4A and 4B, where SAW resonators excite a surface wave in operation. Moreover, in a SAW resonator, the pitch of the IDT is one-half of the acoustic wavelength at the resonance frequency. Additionally, the mark-to-pitch ratio of a SAW resonator IDT is typically close to 0.5 (i.e., the mark or finger width is about one-fourth of the acoustic wavelength at resonance). In an XBAR, the pitch p of the IDT is typically 2 to 20 times the width w of the fingers. in addition, the pitch p of the IDT is typically 2 to 20 times the thickness ts of the piezoelectric layer 110. Moreover, the width of the IDT fingers in an XBAR is not constrained to one-fourth of the acoustic wavelength at resonance. For example, the width of XBAR IDT fingers may be 500 nm or greater, such that the IDT can be fabricated using optical lithography. The thickness tm of the IDT fingers may be from 100 nm to about equal to the width w, as the lithography process typically cannot support a configuration where the thickness is greater than the width. The thickness of the busbars (132, 134 in FIG. 1A) of the IDT may be the same as, less than, greater than, or any combination thereof, the thickness tm of the IDT fingers. It is noted that the XBAR devices described herein are not limited to the ranges of dimensions described herein.

Moreover, unlike a SAW filter, the resonance frequency of an XBAR is dependent on the total thickness of its diaphragm (i.e., in the vertical or thickness direction), including the piezoelectric layer 110, and the front side and back side dielectric layers 212, 214 disposed thereon. In an exemplary aspect, the thickness of one or both dielectric layers (i.e., on the opposing surfaces of the piezoelectric layer) can be varied to change the resonance frequencies of various XBARs in a filter. For example, shunt resonators in a ladder filter circuit may incorporate thicker dielectric layers to reduce the resonance frequencies of the shunt resonators relative to series resonators with thinner dielectric layers, and thus a thinner overall thickness.

Referring back to FIG. 2A, the thickness tfd of the front side dielectric layer 212 over the IDT fingers 238a, 238b may be greater than or equal to a minimum thickness required to cover and passivate the IDT fingers and other conductors on the front side 112 to the piezoelectric layer 110. The minimum thickness may be, for example, 10 nm to 50 nm depending on the material of the front side dielectric layer and method of deposition according to an exemplary aspect. The thickness of the back side dielectric layer 214 may be configured to a specific thickness to adjust the resonance frequency of the resonator as will be described in more detail below.

Although FIG. 2A discloses a configuration in which IDT fingers 238a and 238b are at the front side 112 of the piezoelectric layer 110, alternative configurations can be provided. For example, FIG. 2B shows an alternative configuration (identified as Detail C′) in which the IDT fingers 238a, 238b are at the back side 114 of the piezoelectric layer 110 (i.e., facing the cavity) and are covered by a back side dielectric layer 214. A front side dielectric layer 212 may cover the front side 112 of the piezoelectric layer 110. In exemplary aspects, a dielectric layer disposed on the diaphragm of each resonator can be trimmed or etched to adjust the resonant frequency. However, if the dielectric layer is on the side of the diaphragm facing the cavity, there may be a change in spurious modes (e.g., generated by the coating on the fingers). Moreover, with the passivation layer coated on top of the IDTs, the mark changes, which can also cause spurs. Therefore, disposing the IDT fingers 238a, 238b at the back side 114 of the piezoelectric layer 110 as shown in FIG. 2B may eliminate addressing both the change in frequency as well as the effect it has on spurs as compared when the IDT fingers 238a and 238b are on the front side 112 of the piezoelectric layer 110.

FIG. 2C shows an alternative configuration (identified as Detail C″) in which IDT fingers 238a, 238b are on the front side 112 of the piezoelectric layer 110 and are covered by a front side dielectric layer 212. IDT fingers 238c, 238d are also on the back side 114 of the piezoelectric layer 110 and are also covered by a back side dielectric layer 214. As previously described, the front side and back side dielectric layer 212, 214 are not necessarily the same thickness or the same material.

FIG. 2D shows another alternative configuration (identified as Detail C′″) in which IDT fingers 238a, 238b are on the front side 112 of the piezoelectric layer 110 and are covered by a front side dielectric layer 212. The surface of the front side dielectric layer is planarized. The front side dielectric layer may be planarized, for example, by polishing or some other method. A thin layer of dielectric material having a thickness tp may cover the IDT finger 238a, 238b to seal and passivate the fingers. The dimension TP may be, for example, 10 nm to 50 nm.

Each of the XBAR configurations described above with respect to FIGS. 2A to 2D include a diaphragm spanning over a cavity. However, in an alternative aspect, the bulk acoustic resonator can be solidly mounted in which the diaphragm with IDT fingers is mounted on or above a Bragg mirror, which in turn can be mounted on a substrate.

In particular, FIG. 2E shows a detailed schematic cross-sectional view of a solidly mounted XBAR (SM-XBAR). It is noted that FIG. 2E generally discloses a similar cross section as that of FIG. 1A, except having a solidly mounted configuration. In this aspect, the SM-XBAR includes a piezoelectric layer 110 and an IDT (of which only two fingers 236 are visible) with a dielectric layer 212 disposed on the piezoelectric layer 110 and IDT fingers 236. The piezoelectric layer 110 has parallel, or substantially parallel accounting for manufacturing tolerances, front and back surfaces similar to the configurations described above. Dimension ts is the thickness of the piezoelectric layer 110. The width of the IDT fingers 236 is dimension w, thickness of the IDT fingers is dimension tm, and the IDT pitch is dimension p.

In contrast to the XBAR devices shown in FIG. 1A, the IDT of an SM XBAR in FIG. 2E is not formed on a diaphragm spanning a cavity in the substrate. Instead, an acoustic Bragg reflector 240 is sandwiched between a surface 222 of the substrate 220 and the back surface of the piezoelectric layer 110. The term “sandwiched” means the acoustic Bragg reflector 240 is both disposed between and mechanically attached to a surface 222 of the substrate 220 and the back surface of the piezoelectric layer 110. In some circumstances, layers of additional materials (e.g., one or more dielectric layers) may be disposed between the acoustic Bragg reflector 240 and the surface 222 of the substrate 220 and/or between the Bragg reflector 240 and the back surface of the piezoelectric layer 110. Such additional material layers may be present, for example, to facilitate bonding the piezoelectric layer 110, the acoustic Bragg reflector 240, and the substrate 220.

The acoustic Bragg reflector 240 may be an acoustic mirror configured to reflect at least a portion of the primary acoustic mode excited in the piezoelectric and includes multiple dielectric layers that alternate between materials having high acoustic impedance and materials having low acoustic impedance. The acoustic impedance of a material is the product of the material's shear wave velocity and density. “High” and “low” are relative terms. For each layer, the standard for comparison is the adjacent layers. Each “high” acoustic impedance layer has an acoustic impedance higher than that of both the adjacent low acoustic impedance layers. Each “low” acoustic impedance layer has an acoustic impedance lower than that of both the adjacent high acoustic impedance layers. As discussed above, the primary acoustic mode in the piezoelectric layer of an XBAR is a shear bulk wave. In an exemplary aspect, each layer of the acoustic Bragg reflector 240 has a thickness equal to, or about, one-fourth of the wavelength in the layer of a shear bulk wave having the same polarization as the primary acoustic mode at or near a resonance frequency of the SM XBAR. Dielectric materials having comparatively low acoustic impedance include silicon dioxide, carbon-containing silicon oxide, and certain plastics such as cross-linked polyphenylene polymers. Materials having comparatively high acoustic impedance include hafnium oxide, silicon nitride, aluminum nitride, silicon carbide. All of the high acoustic impedance layers of the acoustic Bragg reflector 240 are not necessarily the same material, and all of the low acoustic impedance layers are not necessarily the same material. In the example of FIG. 2E, the acoustic Bragg reflector 240 has a total of six layers, but an acoustic Bragg reflector may have more than, or less than, six layers in alternative configurations.

The IDT fingers, such as IDT finger 236, 238a, and 238b, may be disposed on a surface of the front side 112 of the piezoelectric layer 110. Alternatively, IDT fingers, such as IDT finger 236, 238a, and 238b, may be disposed in grooves formed in the surface of the front side 112. The grooves may extend partially through the piezoelectric layer. Alternatively, the grooves may extend completely through the piezoelectric layer.

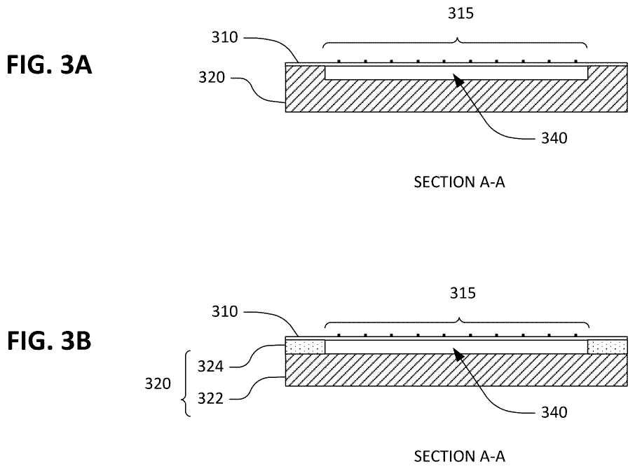

FIG. 3A and FIG. 3B show two exemplary cross-sectional views along the section plane A-A defined in FIG. 1A of XBAR 100. In FIG. 3A, a piezoelectric layer 310, which corresponds to piezoelectric layer 110, is attached directly to a substrate 320, which can correspond to substrate 120 of FIG. 1A. Moreover, a cavity 340, which does not fully penetrate the substrate 320, is formed in the substrate under the portion (i.e., the diaphragm 315) of the piezoelectric layer 310 containing the IDT of an XBAR. The cavity 340 can correspond to cavity 140 of FIGS. 1A and/or 1B in an exemplary aspect. In an exemplary aspect, the cavity 340 may be formed, for example, by etching the substrate 320 before attaching the piezoelectric layer 310. Alternatively, the cavity 340 may be formed by etching the substrate 320 with a selective etchant that reaches the substrate through one or more openings provided in the piezoelectric layer 310.

FIG. 3B illustrates an alternative aspect in which the substrate 320 includes a base 322 and an intermediate layer 324 that is disposed between the piezoelectric layer 310 and the base 322. For example, the base 322 may be silicon (e.g., a silicon support substrate) and the intermediate layer 324 may be silicon dioxide or silicon nitride or some other material, e.g., an intermediate dielectric layer. That is, in this aspect, the base 322 and the intermediate layer 324 are collectively considered the substrate 320. As further shown, cavity 340 is formed in the intermediate layer 324 under the portion (i.e., the diaphragm 315) of the piezoelectric layer 310 containing the IDT fingers of an XBAR. The cavity 340 may be formed, for example, by etching the intermediate layer 324 before attaching the piezoelectric layer 310. Alternatively, the cavity 340 may be formed by etching the intermediate layer 324. In other example embodiments, the cavity 340 may be defined in the intermediate layer 324 by other means from whether the intermediate layer 324 was etched to define the cavity 340. In some cases, the etching may be performed with a selective etchant that reaches the substrate through one or more openings (not shown) provided in the piezoelectric layer 310.

In this case, the diaphragm 315, which can correspond to diaphragm 115 of FIG. 1A, for example, in an exemplary aspect, may be contiguous with the rest of the piezoelectric layer 310 around a large portion of a perimeter of the cavity 340. For example, the diaphragm 315 may be contiguous with the rest of the piezoelectric layer 310 around at least 50% of the perimeter of the cavity 340. As shown in FIG. 3B, the cavity 340 extends completely through the intermediate layer 324. That is, the diaphragm 315 can have an outer edge that faces the piezoelectric layer 310 with at least 50% of the edge surface of the diaphragm 315 coupled to the edge of the piezoelectric layer 310 facing the diaphragm 315. This configuration provides for increased mechanical stability of the resonator.

In other configurations, the cavity 340 may partially extend into, but not entirely through the intermediate layer 324 (i.e., the intermediate layer 324 may extend over the bottom of the cavity on top of the base 322) or may extend through the intermediate layer 324 and into (either partially or wholly) the base 322. As described above, it should be appreciated that the interleaved fingers of the IDT can be disposed on either or both surfaces of the diaphragm 315 in FIGS. 3A and 3B according to various exemplary aspects.

FIG. 4A is a graphical illustration of the primarily excited acoustic mode of interest in an XBAR. FIG. 4B is a graphic illustrating a shear horizontal acoustic mode in an XBAR operating in a third-order antisymmetric (A3) mode. In general, FIGS. 4A and 4B show a small portion of an XBAR 400 and 400′ including a piezoelectric layer 410 and three interleaved IDT fingers 430. The exemplary configurations of XBAR 400 and 400′ can correspond to any of the configurations described above and shown in FIGS. 2A to 2E according to an exemplary aspect. Thus, it should be appreciated that piezoelectric layer 410 can correspond to piezoelectric layer 110 and IDT fingers 430 can be implemented according to any of the configurations of fingers 238a and 238b, for example.

In operation, an RF voltage is applied to the interleaved fingers 430. This voltage creates a time-varying electric field between the fingers. The direction of the electric field is primarily lateral (i.e., predominantly and/or primarily laterally excited), or primarily parallel to the surface of the piezoelectric layer 410, as indicated by the arrows labeled “electric field.” Due to the high dielectric constant of the piezoelectric layer 410, the electric field is highly concentrated in the piezoelectric layer relative to the air. The lateral electric field introduces shear deformation in the piezoelectric layer 410, and thus strongly excites a shear acoustic mode, in the piezoelectric layer 410. In this context, “shear deformation” is defined as deformation in which parallel planes in a material remain parallel and maintain a constant distance while translating relative to each other. In other words, the parallel planes of material are laterally displaced with respect to each other. A “shear acoustic mode” is defined as an acoustic vibration mode in a medium that results in shear deformation of the medium. The shear deformations in the XBAR 400 are represented by the curves 460, with the adjacent small arrows providing a schematic indication of the direction and magnitude of atomic motion. It is noted that the degree of atomic motion, as well as the thickness of the piezoelectric layer 410, have been exaggerated for ease of visualization in FIGS. 4A and 4B. While the atomic motions are predominantly lateral (i.e., horizontal as shown in FIGS. 4A and 4B), the direction of acoustic energy flow of the primarily excited shear acoustic mode is substantially and/or primarily orthogonal to the surface of the piezoelectric layer, as indicated by the arrow 465.

As described in more detail below, XBAR devices can be configured to operate in any suitable acoustic wave mode based on the resonant frequency, for example. FIG. 4A illustrates an XBAR 400 operating in the lowest-order symmetric (A1) mode. FIG. 4B illustrates XBAR 400′ operating in the third-order antisymmetric (A3) mode. The location of the A3 harmonic spur of XBAR devices may be approximated by f_{A3}≈3fᵣ, where fᵣ is the resonance frequency of the main XBAR mode (e.g., as shown in FIG. 4A). That is, the A3 harmonic spur corresponds to a frequency position that is approximately three times the resonance frequency of the XBAR. Thus, in an exemplary aspect, the wavelength for the A3 mode as shown in FIG. 4B is 3/2λ wavelength as opposed to the that the 1/2λ wavelength of the lowest-order symmetric (A1) mode shown in FIG. 4A.

Moreover, it is noted that the degree of atomic motion, as well as the thickness of the piezoelectric layer 410, have been exaggerated for ease of visualization in FIGS. 4A and 4B. While the atomic motions are predominantly lateral (i.e., horizontal as shown in FIG. 4A), the direction of acoustic energy flow of the primarily excited shear acoustic mode is substantially and/or primarily orthogonal to the surface of the piezoelectric layer, as indicated by the arrow 465. It should be appreciated that the relative atomic motion (as indicated by the waves in piezoelectric layer 410) is smaller for XBAR 400 operating in the lowest-order symmetric (S0) mode than XBAR 400′ operating in the third-order antisymmetric (A3) mode.

It is also noted that in general, a bulk acoustic resonator based on shear acoustic wave resonances can achieve better performance than current state-of-the art film-bulk-acoustic-resonators (FBAR) and solidly-mounted-resonator bulk-acoustic-wave (SMR BAW) devices where the electric field is applied in the thickness direction. In such devices, the acoustic mode is compressive with atomic motions and the direction of acoustic energy flow in the thickness direction. In addition, the piezoelectric coupling for shear wave XBAR resonances can be high (>20%) compared to other acoustic resonators. Thus, high piezoelectric coupling enables the design and implementation of microwave and millimeter-wave filters with appreciable bandwidth.

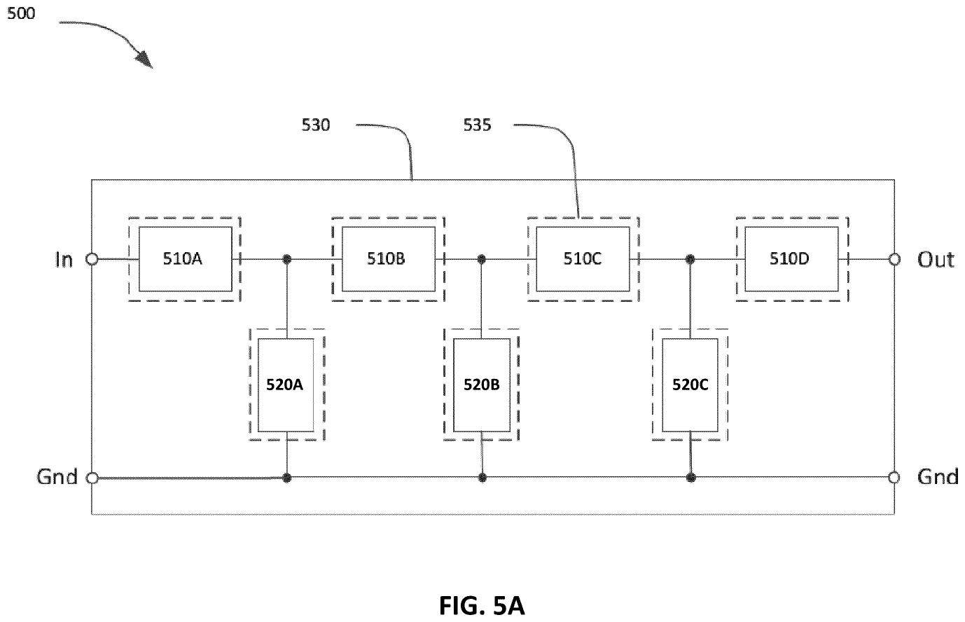

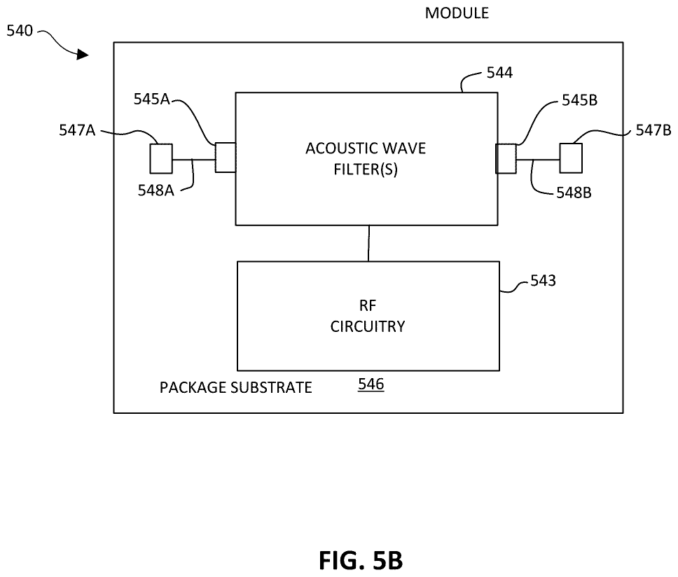

FIG. 5A is a schematic circuit diagram and layout for a high frequency bandpass filter 500 using XBARs, such as the general XBAR configuration 100 (e.g., the bulk acoustic resonators) described above, for example. The filter 500 has a conventional ladder filter architecture, which may include a split-ladder filter architecture wherein the filter is split between multiple chips, that has a plurality of bulk acoustic resonators including four resonators 510A, 510B, 510C, and 510D and three shunt resonators 520A, 520B and 520C. The series resonators 510A, 510B, 510C and 510D are connected in series between a first port and a second port (hence the term “series resonator”). In FIG. 5A, the first and second ports are labeled “In” and “Out”, respectively. However, the filter 500 is bidirectional and either port may serve as the input or output of the filter. At least two shunt resonators, such as the shunt resonators 520A, 520B and 520C, are connected from nodes between respective pairs of series resonators to a ground connection. A filter may contain additional reactive components, such as inductors, not shown in FIG. 5A. All the shunt resonators and series resonators are XBARs (e.g., either of the XBAR configurations 100 and/or 100′ as discussed above) in the exemplary aspect. The inclusion of four series and three shunt resonators is an example. A filter may have more or fewer than seven total resonators, more or fewer than four series resonators, and more or fewer than three shunt resonators. Typically, for a split ladder and non-split-ladder filter architectures, all of the series resonators are connected in series between an input and an output of the filter, and all of the shunt resonators are typically connected between ground and the input, the output, or a node between two series resonators.

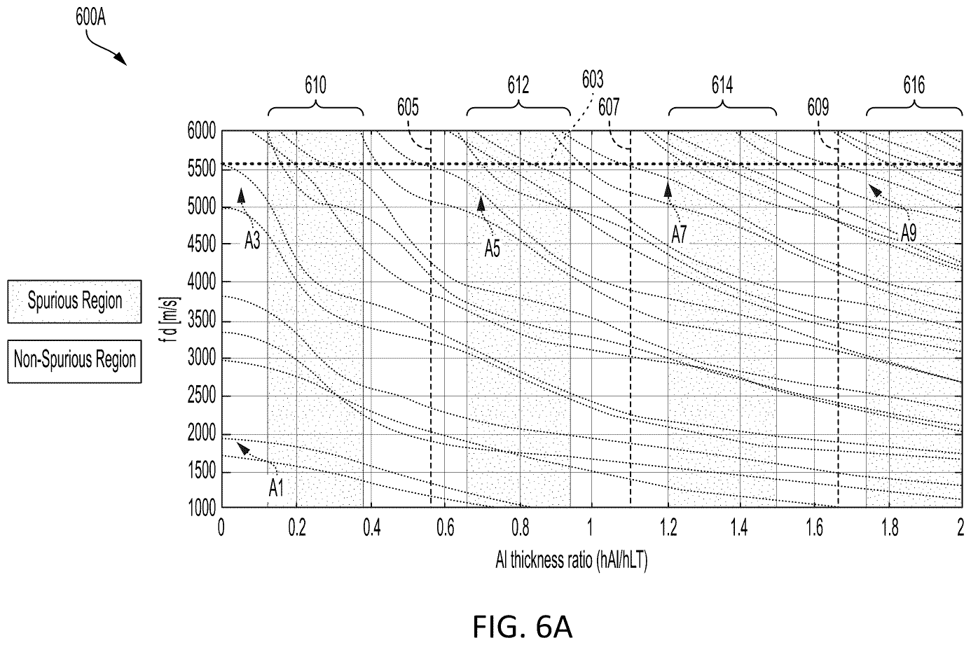

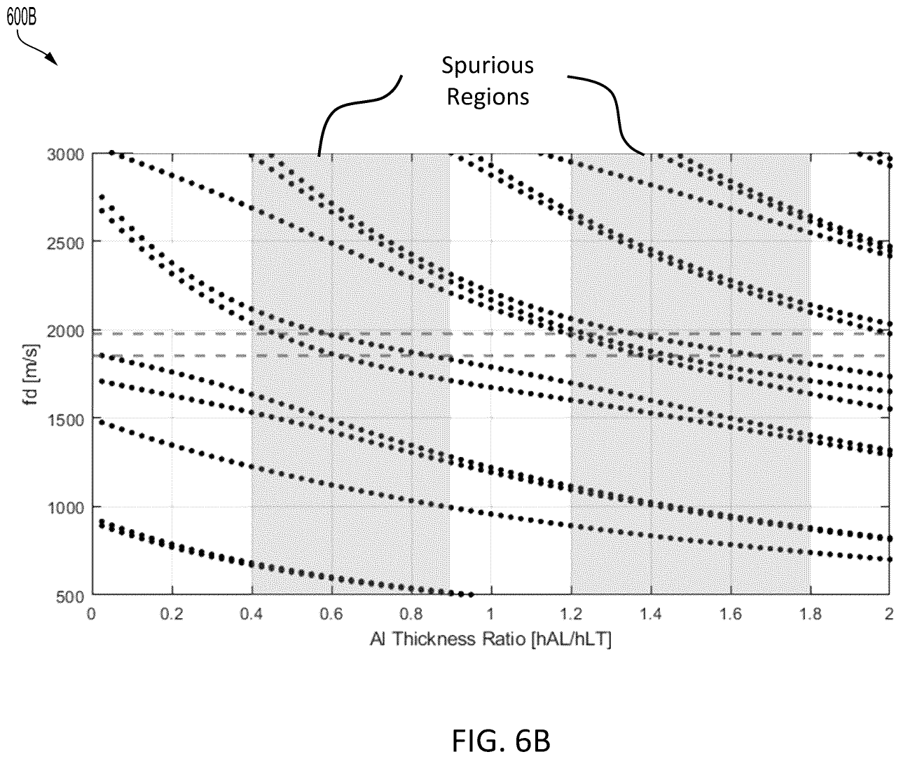

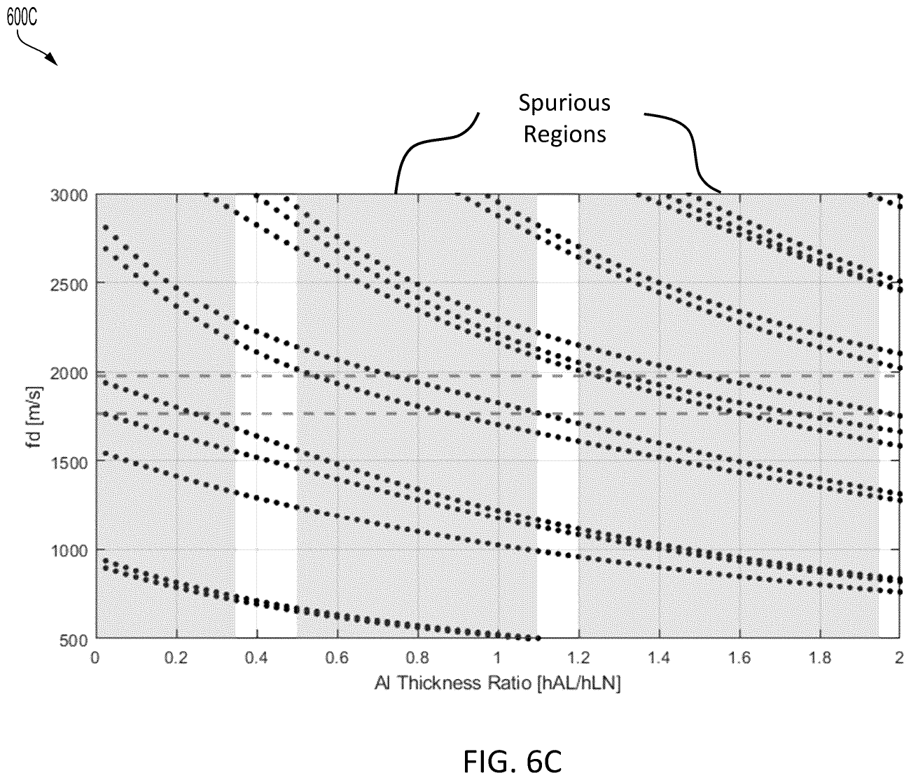

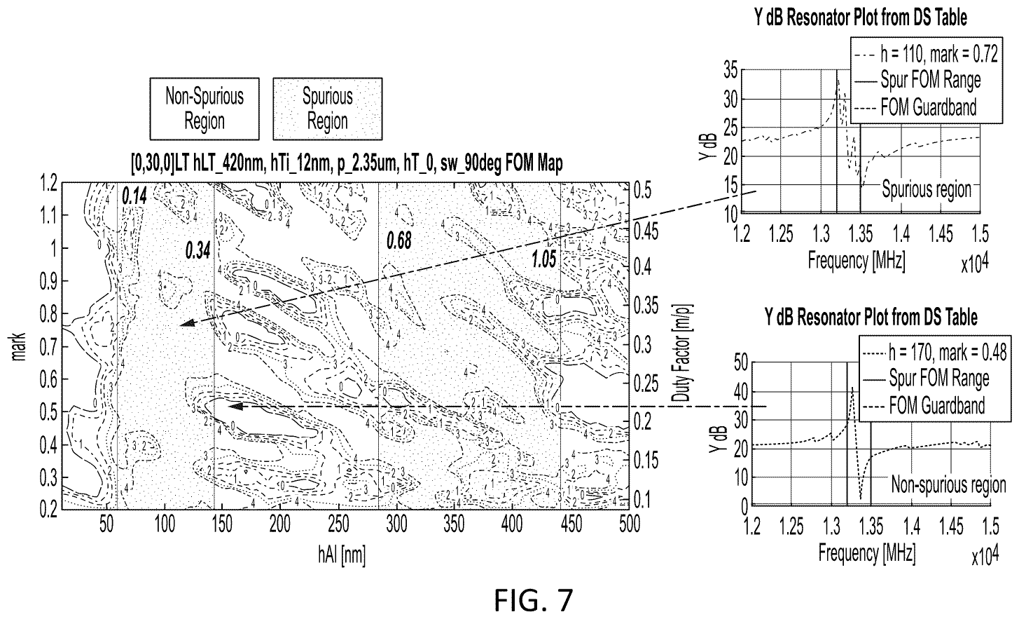

In the exemplary filter 500, the series resonators 510A, 510B, 510C and 510D and the shunt resonators 520A, 520B and 520C of the filter 500 can be formed on at least one, and in some cases a single piezoelectric layer 530 of piezoelectric material bonded to a silicon substrate (not visible). However, in alternative aspects, the individual resonators may each be formed on a separate respective piezoelectric layer for each resonator wherein all resonators are located on the same chip. Moreover, in some aspects, one or more of each of the series and shunt resonators can be formed having IDT thickness optimized for A3 mode operation, as described below with respect to FIGS. 6 and 7, for example. Yet further, different resonators of a filter may be bonded to a separate substrate, for example. This may result in a split-ladder architecture that can include one or a plurality of separate chips that include separate piezoelectric layers and IDTs of one or more bulk acoustic resonators that are then configured together to form the overall split ladder filter.

In an exemplary aspect, each resonator includes a respective IDT (not shown), with at least the fingers of the IDT disposed over a cavity, or an acoustic mirror, in the substrate. In this and similar contexts, the term “respective” means “relating things each to each,” which is to say with a one-to-one correspondence. In FIG. 5A, the cavities are illustrated schematically as the dashed rectangles (such as the rectangle 535). In this example, each IDT is disposed over a respective cavity. In other filters, the IDTs of two or more resonators may be disposed over a single cavity.

Each of the resonators 510A, 510B, 510C, 510D, 520A, 520B and 520C in the filter 500 has a resonance where the admittance (also interchangeably referred to as Y-parameter) of the resonator is very high and an anti-resonance where the admittance of the resonator is very low. The resonance and anti-resonance occur at a resonance frequency and an anti-resonance frequency, respectively, which may be the same or different for the various resonators in the filter 500. In simplified terms, each resonator can be considered a short-circuit at its resonance frequency and an open circuit at its anti-resonance frequency. The input-output transfer function will be near zero at the resonance frequencies of the shunt resonators and at the anti-resonance frequencies of the series resonators. In a typical filter, the resonance frequencies of the shunt resonators are positioned below the lower edge of the filter's passband and the anti-resonance frequencies of the series resonators are positioned above the upper edge of the passband.

The frequency range between resonance and anti-resonance frequencies of a resonator corresponds to the coupling of the resonator. Depending on the design parameters of the filter 500, each of the resonators 510A, 510B, 510C, 510D, 520A, 520B and 520C may have a particular coupling parameter to which the respective resonator is tuned in order to achieve the required frequency response of the filter 500.

According to an exemplary aspect, each of the series resonators 510A, 510B, 510C and 510D and the shunt resonators 520A, 520B and 520C can have an XBAR configuration as described above with respect to FIGS. 1A-2D in which a diaphragm with IDT fingers spans over a cavity. Alternatively, each of the series resonators 510A, 510B, 510C, 510D and the shunt resonators 520A, 520B, and 520C can have an XBAR configuration in which the series resonators 510A, 510B, 510C, 510D and/or the shunt resonators 520A, 520B, and 520C can be solidly mounted on or above a Bragg mirror (e.g., as shown in FIG. 2E), which in turn can be mounted on a substrate. Moreover, each of the series resonators 510A, 510B, 510C and 510D and the shunt resonators 520A, 520B and 520C can also have the layer thicknesses optimized for A3 mode operation, as described below with respect to FIGS. 6 and 7.

FIG. 5B is a schematic diagram of a radio frequency module that includes an acoustic wave filter device according to an exemplary aspect. In particular, FIG. 5B illustrate a radio frequency module 540 that includes one or more acoustic wave filters 544 according to an exemplary aspect. The illustrated radio frequency module 540 also includes radio frequency (RF) circuitry (or RF circuit) 543. In an exemplary aspect, the acoustic wave filters 544 may include one or more of filter 500 including XBARs (e.g., the bulk acoustic resonators described herein), as described above with respect to FIG. 5A. Moreover, in an exemplary aspect, the acoustic wave filter 544 may having optimized layer thicknesses and/or optimized mark to pitch ratio of the IDT fingers for minimizing unwanted spurs during operation in a third-order mode. That is, for example, a ratio of a thickness of the IDT fingers to a thickness of the at least one piezoelectric layer may be between 0.38 and 0.66, and/or a ratio of a mark of the IDT fingers to a pitch of the IDT fingers may be in a range of 0.1 to 0.4. The details of these IDT configurations will be discussed in more detail below.

In addition, the acoustic wave filter 544 shown in FIG. 5B includes terminals 545A and 545B (e.g., first and second terminals). The terminals 545A and 545B can serve, for example, as an input contact and an output contact for the acoustic wave filter 544. Although two terminals are illustrated, any suitable number of terminals can be implemented for a particular application. The acoustic wave filter 544 and the RF circuitry 543 are on a package substrate 546 (e.g., a common substrate) in FIG. 5B. The package substrate 546 can be a laminate substrate. The terminals 545A and 545B can be electrically connected to contacts 547A and 547B, respectively, on the package substrate 546 by way of electrical connectors 548A and 548B, respectively. The electrical connectors 548A and 548B can be bumps or wire bonds, for example. In an exemplary aspect, the acoustic wave filter 544 and the RF circuitry 543 may be enclosed together within a common package, with or without using the package substrate 546.

The RF circuitry 543 can include any suitable RF circuitry. For example, the RF circuitry can include one or more radio frequency amplifiers (e.g., one or more power amplifiers and/or one or more low noise amplifiers), one or more radio frequency switches, one or more additional RF filters, one or more RF couplers, one or more delay lines, one or more phase shifters, or any suitable combination thereof. The RF circuitry 543 can be electrically connected to the one or more acoustic wave filters 544. The radio frequency module 540 can include one or more packaging structures to, for example, provide protection and/or facilitate easier handling of the radio frequency module 540. Such a packaging structure can include an overmold structure formed over the package substrate 546. The overmold structure can encapsulate some or all of the components of the radio frequency module 540.

According to an exemplary aspect of the acoustic resonators (XBARs) described herein, the atomic motions of the XBAR configurations are predominantly lateral (i.e., horizontal as shown in FIGS. 4A and 4B) where the direction of acoustic energy flow, or wave propagation, is substantially orthogonal to the surface of the piezoelectric layer and/or orthogonal to the lateral excitation direction. As also described above, the XBAR devices can be configured to operate in any suitable acoustic wave mode based on the resonant frequency, for example. Example acoustic wave modes include the lowest-order asymmetric (A0) mode, the lowest-order symmetric (S0) mode, the first-order antisymmetric (A1) mode, the first-order symmetric (S1) mode, the second-order asymmetric (A2) mode, the second-order symmetric (S2) mode, the third-order antisymmetric (A3) mode, the third-order symmetric (S3) mode, and so forth.

In general, XBAR resonators operating at overtones (i.e., higher resonant frequencies) such as the A3 third-order asymmetric mode using lithium niobate (LiNbO₃) or lithium tantalate (LiTaO₃) piezoelectric layers are good candidates to meet high frequency, narrow bandwidth filter requirements. Such filter specifications may be required, for example, in 5G or next-generation Wi-Fi applications.

When operating in higher-order modes such as the A3 mode, the metal thickness of the IDT fingers of the XBAR has a large impact on device performance. Generally, relatively high metal thickness improves thermal dissipation and lowers resistive loss of the XBAR. On the other hand, relatively thin metal thickness offers fewer frequency spurs.

Accordingly, an optimal metal thickness of the IDT fingers of an XBAR configured to operate in a higher-order mode, such as the A3 mode, would simultaneously achieve few spurs, low loss, and higher power handling. Achieving these design goals requires careful choice of electrode thickness in the “thick metal” regime for IDT structure to select specific metal thicknesses that minimize spur content at desired frequencies.

FIGS. 6A to 6C are graphs showing mode spectrum of propagating modes within the IDT region (i.e., the piezoelectric layer with the metal IDT layer) and the propagating modes' corresponding frequency multiplied by the metal thickness against an increasing metal thickness. The results shown in FIGS. 6A to 6C are from a computer simulation using a finite element method, for example, and are based on use of a piezoelectric layer, a silicon dioxide dielectric layer, and aluminum IDT fingers. The X axis of FIGS. 6A to 6C represent a ratio of an IDT finger (metal) thickness to the thickness of the piezoelectric layer. The Y axis shows frequency multiplied by the thickness of the piezoelectric layer, measured in m/s.

Analysis of resonance of XBAR devices with thick metal electrodes may consider the metal as acoustically active, yet the displacements in the metal cannot be described as having the same mode as the displacements in the piezoelectric layer. In this aspect, FIG. 6A illustrates a plot 600A that shows modes occurring within two structures within the XBAR: (1) a bare (unmetallized) lithium tantalate piezoelectric layer, which may be found between IDT fingers where a main A3 mode is excited, and (2) a region under the IDT, which includes the piezoelectric layer with the metal IDT layer on top. In this region (2), many spurs and/or odd harmonics of the main A3 mode may be excited.

The dotted horizontal line 603 in FIG. 6A (i.e., at approximately 5500 fd in the Y axis) indicates the resonance frequency of an unmetallized, open, and shorted piezoelectric layer in A3 mode for a given wavelength, corresponding to structure (1) described above. The three dashed vertical lines 605, 607, and 609 in FIG. 6A indicate odd harmonic modes of the main A3 mode within the combined piezoelectric layer and metal structure, corresponding to structure (2) described above. There are two types of modes in structure (2) described above: spurs and the odd harmonic modes represented with vertical lines 605, 607 and 609 in FIG. 6A.

As shown in FIG. 6A, there are white non-spurious regions that define ratios of metal thickness to piezoelectric layer thickness that result in fewer unwanted spurs, and there are textured or dotted spurious regions 610, 612, 614, and 616 between the non-spurious regions that define ratios of metal thickness to piezoelectric layer thickness that result in a higher number of unwanted spurs. Additionally, FIG. 6A shows that the non-spurious regions occur around intersection points between (i) the dashed vertical lines 605, 607 and 607 representing the odd harmonic A5, A7, and A9 modes, respectively, of the composite structure of piezoelectric layer with a metal layer on top and (ii) the horizontal line 603 representing the A3 mode in a bare (unmetallized) piezoelectric layer. As shown, the curved diagonal lines representing the A5, A7 and A9 modes meet at the respective intersections between line 603 and each of lines 605, 607 and 609. This is because fewer spurs occur when the metal thickness is selected such that the resonance of the bare (unmetallized) piezoelectric layer that is found between IDT fingers (A3 in the example of FIG. 6A) matches the resonance mode of piezoelectric layer with the metal layer on top (this is shown at the intersection points with the dashed vertical lines 603, 607 and 609 of modes A5, A7, and A9 in FIG. 6A). In other words, the frequency of the IDT acoustic mode (of the piezoelectric layer with the metal layer on top) matches the shear acoustic wave within the piezoelectric layer (resonance of the bare piezoelectric layer).

In the exemplary aspect of FIG. 6A, the selected metal thickness may be in the non-spurious regions defined by ranges of 0-0.12, 0.38-0.66, 0.94-1.2, and 1.5-1.74 for the ratio of metal thickness to the thickness of the lithium tantalate piezoelectric layer (i.e., the ranges for values of the x axis in FIG. 6A). As described above, in these ranges the resonance of the unmetallized piezoelectric layer is well-matched to the resonance mode of the composite piezoelectric layer and metal, decreasing the presence of unwanted spurs.

According to an exemplary aspect, the ratio of the metal thickness to the thickness of the piezoelectric layer is set to be in the range of 0.38 to 0.66. Ratio values in this range ensure operation within the non-spurious region shown in FIG. 6A, as well as ensure a thick enough metal layer to take advantage of the higher thermal dissipation and lower resistive loss while maintaining a thickness of the piezoelectric layer within design and manufacturing parameters. That is, operation within the other non-spurious regions shown in FIG. 6A, which are defined by ratio ranges of 0-0.12, 0.94-1.2, and 1.5-1.74, may have practical or design disadvantages that require the metal thickness to be not thick enough or require the piezoelectric layer to be too thin or too thick.

An additional advantage of operation within the non-spurious regions is that FIG. 6A shows that the area near the resonance of the unmetallized piezoelectric layer (i.e., the area near the dotted horizontal line) within the non-spurious regions is free of unwanted modes/spurs. More particularly, the relatively low number of unwanted modes/spurs (illustrated by the curved diagonally extending dotted lines) is shown in FIG. 6A as a relatively low number of dotted lines intersecting the dashed horizontal line 603 in the non-spurious regions (between regions 610, 612, 614 and 616), which indicates that there are fewer unwanted propagating modes that may affect XBAR devices that have ratios of metal thickness to the thickness of the piezoelectric layer that fall within the above-described ranges defining the non-spurious regions.

In the exemplary aspect of FIG. 6A, the XBAR device has a ratio of 5.5 of the pitch of the IDT fingers to the thickness of the piezoelectric layer, the IDT fingers are aluminum, and the piezoelectric layer is a lithium tantalate plate having Euler angles of [0, 30, 0]. However, other XBAR configurations may be analyzed to determine appropriate metal thickness to achieve operation within the non-spurious regions.

FIGS. 6B and 6C are similar plots as described above with respect to FIG. 6A and generally have the same X axis and Y axis parameters. In this aspect, FIGS. 6B and 6C each provide respective plots 600B and 600C that show modes occurring within two structures within the XBAR: (1) a bare (unmetallized) piezoelectric layer, which may be found between IDT fingers where a main S2 mode is excited, and (2) a region under the IDT, which includes the piezoelectric layer with the metal IDT layer on top. In this region (2), many spurs (e.g., the identified “spurious regions”) and/or odd harmonics of the main S2 mode may be excited. In the exemplary aspects of FIGS. 6B and 6C, the XBAR device has IDT fingers comprising aluminum, and the piezoelectric layer has Euler angles of [0, 30, 0]. The plot shown in FIG. 6B is based on a piezoelectric layer formed from lithium tantalate, and the plot shown in FIG. 6B is based on a piezoelectric layer formed from lithium niobate.

As similarly described above with respect to FIG. 6A, the relatively low number of unwanted modes/spurs (illustrated by the curved diagonally extending dotted lines) is shown in the plots 600B and 600C of FIGS. 6B and 6C as a relatively low number of dotted lines intersecting the dashed horizontal line in the non-spurious regions, which indicates that there are fewer unwanted propagating modes that may affect XBAR devices that have ratios of metal thickness to the thickness of the piezoelectric layer that fall within the ranges defining the non-spurious regions. Thus, according to the exemplary aspect in FIG. 6B, plot 600B illustrates that the selected optimal metal thickness for an XBAR, which is configured to operate in the S2 mode, may be in the non-spurious regions defined by ranges of 0-0.4, 0.9-1.2, and 1.8-2.0 for the ratio of metal thickness to the thickness of the lithium tantalate piezoelectric layer (i.e., the ranges for values of the x axis in FIG. 6B). Similarly, in the exemplary aspect in FIG. 6C, plot 600C illustrates that the selected optimal metal thickness for an XBAR, which is configured to operate in the S2 mode, may be in the non-spurious regions defined by ranges of 0.35-0.5, 1.1-1.2, and 1.95-2.0 for the ratio of metal thickness to the thickness of the lithium niobate piezoelectric layer (i.e., the ranges for values of the x axis in FIG. 6C).

FIG. 7 is a graph identifying preferred combinations of IDT finger thickness, mark of the IDT fingers, and a ratio of the thickness of the IDT fingers to the thickness of the piezoelectric layer. Specifically, FIG. 7 is a figure of merit (FOM) map corresponding to the A3 resonance of the unmetallized piezoelectric layer (i.e., the dashed horizontal line 603 in FIG. 6A). The plot shown in FIG. 7 is from a computer simulation using a finite element method, for example.

As shown, the X axis of FIG. 7 indicates the metal thickness of the IDT fingers in nanometers (hAl), the Y axis indicates the mark or width of the IDT fingers in microns and the areas in the FOM map are labeled with the number of undesirable frequency spurs occur in those areas. Accordingly, areas labeled 0 or 1 are desirable in the FOM map, especially such areas with a relatively large area, allowing for variations in the metal thickness or the mark of the IDT fingers for design or manufacturing reasons while remaining in the desirable 0- or 1-spur areas.

The vertical lines in FIG. 7 define the boundaries of the spurious and non-spurious regions of FIG. 6A and are marked with the corresponding ratio of the thickness of the IDT fingers to the thickness of the lithium tantalate piezoelectric layer, from FIG. 6A. Consistent with the indications of FIG. 6A, the non-spurious regions of FIG. 7 include a number of large 0-spur areas. As noted above, the non-spurious region defined by ratio range of 0.38 to 0.66 may be most advantageous based on design and manufacturing parameters and corresponds to the non-spurious range bound by the vertical lines labeled 0.34 and 0.68 in FIG. 7. FIG. 7 shows several large 0-spur areas within this non-spurious range, which is consistent with its low-spur characterization in FIG. 6A.

The additional data regarding the mark of the IDT fingers provided in FIG. 7 allows for the mark of the IDT fingers to be optimized along with the metal thickness to ensure operation within a relatively spur-free space. For example, within the non-spurious region defined by the lines labeled with ratios 0.34 and 0.68 in FIG. 7, relatively large 0-spur areas exist for values of the mark lower than 1.

Considering that an IDT finger mark lower than 0.5 microns may not be practical, the optimal mark range may be defined as 0.5 microns to 1 micron in some cases based on manufacturing tolerances. Because the pitch of the XBAR described in FIG. 7 is set to 2.35 microns, the optimal mark-to-pitch ratio range for the XBAR device described in FIG. 7 is 0.1 to 0.4. The mark-to-pitch ratio may be commonly referred to as a duty factor. While the piezoelectric thickness may have a dominant influence on the resonance frequency, the duty factor may also have an influence, albeit relatively smaller than the influence of piezoelectric thickness. Further, the duty factor may also have an influence on coupling. For example, maximum coupling may occur for IDT mark/pitch between 0.40 and 0.45. Coupling decreases with decreasing mark/pitch. However, 27% coupling is available at mark/pitch value of about 0.12, which is sufficient for most filter applications.

In the exemplary aspect of FIG. 7, the XBAR device has a ratio of 5.5 of the pitch of the IDT fingers to the thickness of the piezoelectric layer, the IDT fingers are aluminum, and the piezoelectric layer is a lithium tantalate plate having Euler angles of [0, 30, 0] and a thickness of 420 nm. The A3 resonance of the unmetallized piezoelectric layer shown in FIG. 7 is based on an applied frequency between 13.2 GHz and 13.5 GHz. In other words, the resonant frequency of the A3 mode is within the range of 13.2 GHz to 13.5 GHz. However, other XBAR configurations and applied frequencies may be analyzed to determine appropriate metal thickness and IDT finger mark to achieve operation within the non-spurious regions.

The two resonator performance plots on the right-hand side of FIG. 7 further illustrate the performance advantages of operating within a 0-spur area of the non-spurious region, as opposed to operating within the spurious region. As shown in the top resonator plot localized to the spurious region of FIG. 7, the resonator performance within the FOM frequency range includes several unwanted spurs. In the top resonator plot, the metal thickness is set at 110 nm and the mark of the IDT fingers is set at 0.7 microns.

On the other hand, the lower resonator plot on the right-hand side of FIG. 7 shows the improved resonator performance achieved when operating within a 0-spur area of the non-spurious region. As shown in the FOM frequency range of this plot, the resonance and anti-resonance frequencies of the resonator are clearly identifiable, with a reduction of unwanted spurs therebetween. In the bottom resonator plot, the metal thickness is set to 170 nm and the mark of the IDT finger is set to 0.48 with a mark to pitch ratio of about 0.20.

Accordingly, for operation in the third-order antisymmetric A3 mode, optimal values of relatively large metal thicknesses exist where spur content is small. These optimal values for operation in the A3 mode differ from related metal thickness values that are optimal for devices operating in an A1 mode, for example. For 5G applications, operation in the A3 modes using the disclosed optimal values of relatively large metal thicknesses may be suitable, for example, for XBAR devices operating within Frequency Range 3 (FR3) bands, since the smaller bandwidth that may be associated with FR3 bands is more tolerable to metal modes and associated harmonics.

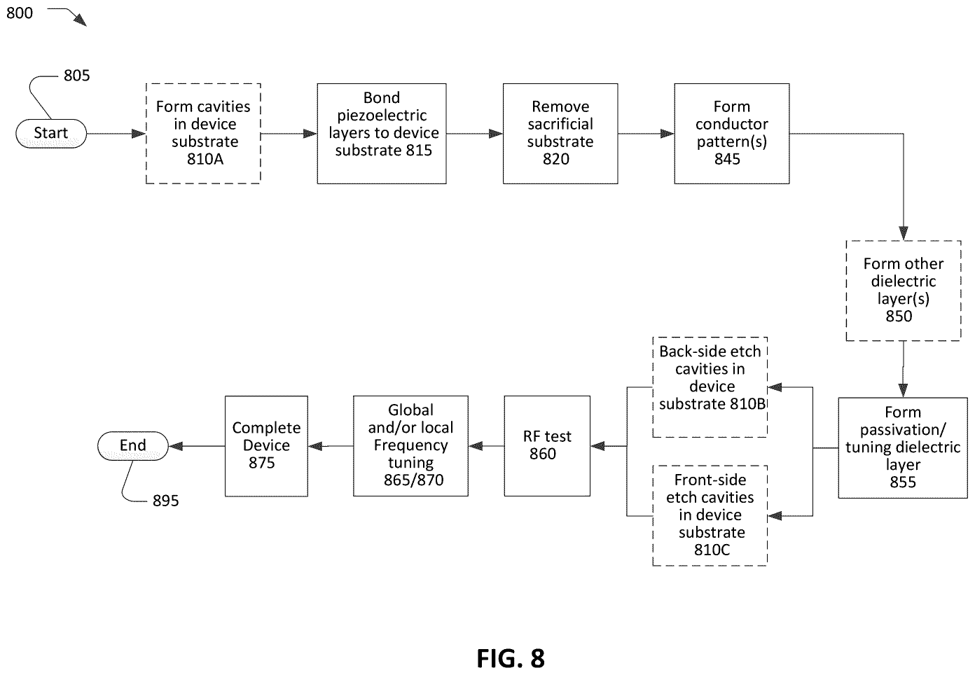

FIG. 8 is a simplified flow chart summarizing a process 800 for fabricating a filter device incorporating XBARs. Specifically, the process 800 is for fabricating a filter device including multiple XBARs. The process 800 starts at 805 with a device substrate and a thin layer of piezoelectric material disposed on a sacrificial substrate. The process 800 ends at 895 with a completed filter device. The flow chart of FIG. 8 includes only major process steps. Various conventional process steps (e.g., surface preparation, cleaning, inspection, baking, annealing, monitoring, testing, etc.) may be performed before, between, after, and during the steps shown in FIG. 8.

It should be appreciated that while FIG. 8 generally describes a process 800 for fabricating a single filter device, multiple filter devices may be fabricated simultaneously on a common wafer (consisting of a piezoelectric layer bonded to a substrate). In this case, each step of the process 800 may be performed concurrently on all of the filter devices on the wafer.

The flow chart of FIG. 8 captures three variations of the process 800 for making an XBAR which differ in whether and how cavities are formed in the device substrate. The cavities may be formed at steps 810A, 810B, or 810C or not at all (e.g., in the case of a solidly-mounted XBAR). Only one or none of steps 810A, 810B, and 810C is performed in each of the three variations of the process 800.

The piezoelectric layer may be, for example, a lithium niobate plate or a lithium tantalate plate, either of which may be Z-cut, rotated Z-cut, Y-cut, rotated Y-cut, or rotated YX-cut. For historical reasons, a rotated Y-cut plate configuration may be commonly referred to as “Y-cut”, where the “cut angle” is the angle between the y axis and the normal to the plate. The “cut angle” is equal to β+90°. For example, a plate with Euler angles [0°, 30°, 0°] is commonly referred to as “120° rotated Y-cut”. In some embodiments, the piezoelectric layer's z axis may be normal to the plate surface and the y axis orthogonal to the IDT fingers. Such piezoelectric plates have Euler angles of 0, 0, 90°. Further embodiments may include a piezoelectric layer with Euler angles θ, β, 90°, where β is in the range from −15° to +5°, 0°≤β≤60, or any combination thereof. The piezoelectric layer may be some other material and/or some other cut. The device substrate may preferably be silicon. The device substrate may be some other material that allows formation of deep cavities by etching or other processing.

In one variation of the process 800, one or more cavities are formed in the device substrate at 810A, before the piezoelectric layer is bonded to the substrate at 815. A separate cavity may be formed for each resonator in a filter device. The one or more cavities may be formed using conventional photolithographic and etching techniques. Typically, the cavities formed at 810A will not penetrate through the device substrate. As described above, the cavities may be in a base, such as silicon, of the substrate. Alternatively, the cavities may be in an intermediate layer, such as silicon dioxide, of the substrate.

At 815, the piezoelectric layer is bonded to the device substrate. The piezoelectric layer and the device substrate may be bonded by a wafer bonding process. For example, the thickness of the piezoelectric layer may be consistent with an optimal ratio of the metal thickness of the IDT fingers to the thickness of the piezoelectric layer for minimizing unwanted spurs, as described above with reference to FIGS. 6 and 7 of the present disclosure. Typically, the mating surfaces of the device substrate and the piezoelectric layer are highly polished. One or more layers of intermediate materials, such as an oxide or metal, may be formed or deposited on the mating surface of one or both of the piezoelectric layer and the device substrate. For example, high acoustic impedance and low acoustic impedance layers of the Bragg stack may be formed or deposited on the mating surface or one or both of the piezoelectric layer and device substrate. One or both mating surfaces may be activated using, for example, a plasma process. The mating surfaces may then be pressed together with considerable force to establish molecular bonds between the piezoelectric layer and the device substrate or intermediate material layers.

At 820, the sacrificial substrate may be removed. For example, the piezoelectric layer and the sacrificial substrate may be a wafer of piezoelectric material that has been ion implanted to create defects in the crystal structure along a plane that defines a boundary between what will become the piezoelectric layer and the sacrificial substrate. At 820, the wafer may be split along the defect plane, for example by thermal shock, detaching the sacrificial substrate and leaving the piezoelectric layer bonded to the device substrate. The exposed surface of the piezoelectric layer may be polished or processed in some manner after the sacrificial substrate is detached.

Thin layers of single-crystal piezoelectric materials laminated to a non-piezoelectric substrate are commercially available. At the time of this application, both lithium niobate and lithium tantalate layers are available bonded to various substrates including silicon, quartz, and fused silica. Thin layers of other piezoelectric materials may be available now or in the future. The thickness of the piezoelectric layer may be between 300 nm and 1000 nm. When the substrate is silicon, a layer of SiO₂ may be disposed between the piezoelectric layer and the substrate. When a commercially available piezoelectric layer/device substrate laminate is used, steps 810A, 815, and 820 of the process 800 are not performed.

Moreover, a first conductor pattern, including IDTs of each XBAR, is formed at 845 by depositing and patterning one or more conductor layers on the front side of the piezoelectric layer (e.g., piezoelectric layer 110 as described above). The conductor layer may be, for example, aluminum, an aluminum alloy, copper, a copper alloy, or some other conductive metal. For example, the thickness of the conductor layers formed at 845 is consistent with the optimal ratio of metal thickness of the IDT fingers to the thickness of the piezoelectric layer for minimizing unwanted spurs, as described above with reference to FIGS. 6 and 7 of the present disclosure. Additionally, the mark to pitch ratio of the IDT fingers formed at 845 may be consistent, for example, with an optimized mark to pitch ratio for minimizing unwanted spurs, as described above with reference to FIG. 7. One or more layers of other materials may be disposed below (i.e., between the conductor layer and the piezoelectric layer) and/or on top of the conductor layer. For example, a thin film of titanium, chrome, or other metal may be used to improve the adhesion between the conductor layer and the piezoelectric layer. A second conductor pattern of gold, aluminum, copper or other higher conductivity metal may be formed over portions of the first conductor pattern (for example the IDT bus bars and interconnections between the IDTs).

Each conductor pattern may be formed at 845 by depositing the conductor layer and, optionally, one or more other metal layers in sequence over the surface of the piezoelectric layer. The excess metal may then be removed by etching through patterned photoresist. The conductor layer can be etched, for example, by plasma etching, reactive ion etching, wet chemical etching, or other etching techniques.

Alternatively, each conductor pattern may be formed at 845 using a lift-off process. Photoresist may be deposited over the piezoelectric layer, and patterned to define the conductor pattern. The conductor layer and, optionally, one or more other layers may be deposited in sequence over the surface of the piezoelectric layer. The photoresist may then be removed, which removes the excess material, leaving the conductor pattern. In either case, the conductor pattern can be formed to include the grating elements as described herein.

At 850, one or more frequency setting dielectric layer(s) may be formed by depositing one or more layers of dielectric material on the front side of the piezoelectric layer. For example, a dielectric layer may be formed over the shunt resonators to lower the frequencies of the shunt resonators relative to the frequencies of the series resonators. The one or more dielectric layers may be deposited using a conventional deposition technique such as physical vapor deposition, atomic layer deposition, chemical vapor deposition, or some other method. One or more lithography processes (using photomasks) may be used to limit the deposition of the dielectric layers to selected areas of the piezoelectric layer. For example, a mask may be used to limit a dielectric layer to cover only the shunt resonators.

At 855, a passivation/tuning dielectric layer may be deposited over the piezoelectric layer and conductor patterns. The passivation/tuning dielectric layer may cover the entire surface of the filter except for pads for electrical connections to circuitry external to the filter. In some instantiations of the process 800, the passivation/tuning dielectric layer may be formed after the cavities in the base of the device substrate and/or intermediate layer of the substrate are etched at either 810B or 810C.

In a second variation of the process 800, one or more cavities are formed in the back surface of the base of the device substrate and/or the intermediate layer of the substrate at 810B. A separate cavity may be formed for each resonator in a filter device. The one or more cavities may be formed using an anisotropic or orientation-dependent dry or wet etch to open holes through the back side of the device substrate to the piezoelectric layer. In this case, the resulting resonator devices will have a cross-section as shown in FIG. 1A or 1B.

In a third variation of the process 800, one or more cavities in the form of recesses in the device substrate may be formed at 810C by etching the substrate using an etchant introduced through openings in the piezoelectric layer. A separate cavity may be formed for each resonator in a filter device. The one or more cavities formed at 810C will not penetrate through the device substrate.

Ideally, most or all of the filter devices on a wafer will meet a set of performance requirements. However, normal process tolerances will result in variations in parameters such as the thicknesses of dielectric layer formed at 850 and 855, variations in the thickness and line widths of conductors and IDT fingers formed at 845, and variations in the thickness of the piezoelectric layer. These variations contribute to deviations of the filter device performance from the set of performance requirements.

To improve the yield of filter devices meeting the performance requirements, frequency tuning may be performed by selectively adjusting the thickness of the passivation/tuning layer deposited over the resonators at 855. The frequency of a filter device passband can be lowered by adding material to the passivation/tuning layer, and the frequency of the filter device passband can be increased by removing material to the passivation/tuning layer. Typically, the process 800 is biased to produce filter devices with passbands that are initially lower than a required frequency range but can be tuned to the desired frequency range by removing material from the surface of the passivation/tuning layer.

At 860, a probe card or other means may be used to make electrical connections with the filter to allow radio frequency (RF) tests and measurements of filter characteristics such as input-output transfer function. Typically, RF measurements are made on all, or a large portion, of the filter devices fabricated simultaneously on a common piezoelectric layer and substrate.

At 865, global frequency tuning may be performed by removing material from the surface of the passivation/tuning layer using a selective material removal tool such as, for example, a scanning ion mill as previously described. “Global” tuning is performed with a spatial resolution equal to or larger than an individual filter device. The objective of global tuning is to move the passband of each filter device towards a desired frequency range. The test results from 860 may be processed to generate a global contour map indicating the amount of material to be removed as a function of two-dimensional position on the wafer. The material is then removed in accordance with the contour map using the selective material removal tool.

At 870, local frequency tuning may be performed in addition to, or instead of, the global frequency tuning performed at 865. “Local” frequency tuning is performed with a spatial resolution smaller than an individual filter device. The test results from 860 may be processed to generate a map indicating the amount of material to be removed at each filter device. Local frequency tuning may require the use of a mask to restrict the size of the areas from which material is removed. For example, a first mask may be used to restrict tuning to only shunt resonators, and a second mask may be subsequently used to restrict tuning to only series resonators (or vice versa). This would allow independent tuning of the lower band edge (by tuning shunt resonators) and upper band edge (by tuning series resonators) of the filter devices.

After frequency tuning at 865 and/or 870, the filter device is completed at 875. Actions that may occur at 875 include forming bonding pads or solder bumps or other means for making connection between the device and external circuitry (if such pads were not formed at 845); excising individual filter devices from a wafer containing multiple filter devices; other packaging steps; and additional testing. After each filter device is completed, the process ends at 895.

It is noted that throughout this description, the embodiments and examples shown should be considered as examples, rather than limitations on the apparatus and procedures disclosed or claimed. Although many of the examples presented herein involve specific combinations of method acts or system elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

What is claimed:

1. A bulk acoustic resonator device configured for operating in a third-order antisymmetric (A3) mode, the bulk acoustic resonator device comprising:
a substrate;
a piezoelectric layer connected directly or via one or more intermediate layers to the substrate; and
an interdigital transducer (IDT) on a surface of the piezoelectric layer, the IDT including interleaved IDT fingers extending from first and second busbars respectively,
wherein a ratio of a thickness of the IDT fingers to a thickness of the piezoelectric layer is between 0.38 and 0.66, the thickness of the IDT fingers and the thickness of the piezoelectric layer being measured in a direction normal to the surface of the piezoelectric layer.

2. The bulk acoustic resonator device of claim 1, wherein the piezoelectric layer is one of (i) at least one lithium niobate plate or (ii) at least one lithium tantalate plate, and the IDT fingers are aluminum.

3. The bulk acoustic resonator device of claim 1, wherein:
a ratio of a mark of the IDT fingers to a pitch of the IDT fingers is in a range of 0.1 to 0.4, and
the mark of the IDT fingers and the pitch of the IDT fingers being measured in a direction that is substantially parallel to the surface of the piezoelectric layer.

4. The bulk acoustic resonator device of claim 1, wherein a ratio of a pitch of the IDT fingers to the thickness of the piezoelectric layer is 5.5.

5. The bulk acoustic resonator device of claim 1, further comprising a diaphragm comprising a portion of the piezoelectric layer over a cavity of the bulk acoustic resonator device.

6. The bulk acoustic resonator device of claim 1, further comprising at least one of:
a front side dielectric layer at a front surface of the piezoelectric layer; or
a back side dielectric layer at a back surface of the piezoelectric layer.

7. The bulk acoustic resonator device of claim 1, wherein the piezoelectric layer and the IDT are configured such that a radio frequency signal applied to the IDT excites a primarily shear acoustic mode within the piezoelectric layer.

8. The bulk acoustic resonator device of claim 7, wherein the radio frequency signal applied to the IDT excites an IDT acoustic mode among structures of the IDT, a frequency of the IDT acoustic mode being matched to a primarily shear acoustic wave within the piezoelectric layer.

9. The bulk acoustic resonator device of claim 7, wherein the radio frequency signal is within a range defined by 13.2 GHz and 13.5 GHz, inclusive.

10. The bulk acoustic resonator device of claim 1, wherein the bulk acoustic resonator device is configured to excite a bulk shear wave having a propagation direction perpendicular to a direction of a primarily laterally excited electric field generated by the IDT, the electric field being primarily laterally excited when atomic motion of the bulk shear wave is primarily horizontal in the piezoelectric layer, while the bulk shear wave propagates in a direction primarily perpendicular to the direction of atomic motion.

11. A bulk acoustic resonator device comprising:
a substrate;
a piezoelectric layer attached directly or via one or more intermediate layers to the substrate; and
an interdigital transducer (IDT) on a surface of the piezoelectric layer, the IDT including interleaved IDT fingers extending from first and second busbars respectively,
wherein a ratio of a thickness of the IDT fingers to a thickness of the piezoelectric layer is between 0.38 and 0.66, the thickness of the IDT fingers and the thickness of the piezoelectric layer being measured in a direction normal to the surface of the piezoelectric layer, and
wherein a ratio of a mark of the IDT fingers to a pitch of the IDT fingers is in a range of 0.1 to 0.4, the mark of the IDT fingers and the pitch of the IDT fingers being measured in a direction that is substantially parallel to the surface of the piezoelectric layer.

12. The bulk acoustic resonator device of claim 11, wherein the piezoelectric layer is one of (i) at least one lithium niobate plate or (ii) at least one lithium tantalate plate, and the IDT fingers are aluminum.

13. The bulk acoustic resonator device of claim 11, wherein the acoustic resonator device is configured to operate in a third-order antisymmetric (A3) mode.

14. The bulk acoustic resonator device of claim 11, wherein a ratio of the pitch of the IDT fingers to the thickness of the piezoelectric layer is 5.5.

15. The bulk acoustic resonator device of claim 11, further comprising a diaphragm comprising a portion of the piezoelectric layer spanning a cavity of the acoustic resonator device.

16. The bulk acoustic resonator device of claim 11, further comprising at least one of:
a front side dielectric layer at a front surface of the piezoelectric layer; or
a back side dielectric layer at a back surface of the piezoelectric layer.

17. The bulk acoustic resonator device of claim 11, wherein the piezoelectric layer and the IDT are configured such that a radio frequency signal applied to the IDT excites a primarily shear acoustic mode within the piezoelectric layer.

18. The bulk acoustic resonator device of claim 17, wherein the radio frequency signal is within a range defined by 13.2 GHz and 13.5 GHz, inclusive.

19. The bulk acoustic resonator device of claim 11, wherein the bulk acoustic resonator device is configured to excite a bulk shear wave having a propagation direction perpendicular to a direction of a primarily laterally excited electric field generated by the IDT, the electric field being primarily laterally excited when atomic motion of the bulk shear wave is primarily horizontal in the piezoelectric layer, while the bulk shear wave propagates in a direction primarily perpendicular to the direction of atomic motion.

20. A radio frequency module, comprising:
a filter device having a plurality of acoustic resonators configured to operate in a third-order antisymmetric (A3) mode; and
a radio frequency circuit coupled to the filter device, the filter device and the radio frequency circuit being enclosed within a common package,
wherein at least one of the plurality of acoustic resonators includes:
a substrate;
a piezoelectric layer connected directly or via one or more intermediate layers to the substrate; and
an interdigital transducer (IDT) on a surface of the piezoelectric layer, the IDT including interleaved IDT fingers extending from first and second busbars respectively,
wherein a ratio of a thickness of the IDT fingers to a thickness of the piezoelectric layer is between 0.38 and 0.66, the thickness of the IDT fingers and the thickness of the piezoelectric layer being measured in a direction normal to the surface of the piezoelectric layer.
